(19) United States
(12) Patent Application Publication
(10) Pub. No.: US 2026/0366196 A1
(43) Pub. Date: Nov. 19, 2026

(54) LOW-PRESSURE CHEMICAL VAPOR DEPOSITION-BASED ETCHING OF GALLIUM OXIDE USING SOLID SOURCE GALLIUM

(71) Applicant: University of Massachusetts, Westborough, MA (US)

(72) Inventors: A F M Anhar Uddin Bhuiyan, Lowell, MA (US); Saleh Ahmed Khan, Lowell, MA (US)

(73) Assignee: University of Massachusetts, Westborough, MA (US)

(21) Appl. No.: 19/676,052

(22) Filed: May 13, 2026

Related U.S. Application Data
(60) Provisional application No. 63/804,855, filed on May 13, 2025.

(51) Int. Cl. C30B 33/12; C30B 25/08; C30B 29/16

(52) U.S. Cl. CPC C30B 33/12; C30B 25/08; C30B 29/16

(57) ABSTRACT

A method of etching gallium oxide in a low-pressure chemical vapor deposition (LPCVD) system is disclosed. A gallium oxide substrate or epitaxial wafer is placed inside a LPCVD chamber, where the gallium oxide includes a homoepitaxial layer on a native gallium oxide substrate or a heteroepitaxial layer on a foreign substrate. The gallium oxide is unintentionally doped or doped with one or more dopants selected from silicon, tin, germanium, magnesium, nitrogen, iron, or combinations thereof. A gallium source is placed within or fluidically coupled to the LPCVD chamber. Gallium vapor is generated from the gallium source under reduced-pressure conditions within the LPCVD chamber. Gallium vapor is transported to a surface of the gallium oxide substrate or epitaxial wafer through carrier-gas-mediated diffusion, convection, or combinations thereof. The gallium oxide is etched by a thermally activated reaction between gallium and gallium oxide to form and remove volatile gallium suboxide species.

### CROSS-REFERENCE TO RELATED APPLICATIONS

This patent document claims priority to earlier filed U.S. Provisional Application Ser. No. 63/804,855, filed on May 13, 2025, the entire contents of which are incorporated herein by reference.

### STATEMENT REGARDING FEDERALLY SPONSORED RESEARCH OR DEVELOPMENT

This invention was made with government support under Award Nos. 2501623 and 2532898 awarded by National Science Foundation. The government has certain rights in the invention.

### BACKGROUND OF THE INVENTION

The ultra-wide bandgap β-Ga₂O₃ has garnered significant attention for next-generation power and RF electronics due to its ultrawide bandgap (~4.8 eV), high breakdown field strength (~8 MV/cm), controllable n-type doping, and the availability of large-area melt-grown native substrates¹⁻⁴. These properties collectively yield an exceptionally high Baliga's figure of merit, surpassing those of GaN and SiC, and establishing β-Ga₂O₃ as a compelling platform for kilovolt-class power conversion, high-frequency amplification, and radiation-hardened electronics⁵⁻¹². Importantly, the ability to grow thick epitaxial layers using scalable techniques such as Metalorganic Chemical Vapor Deposition (MOCVD)¹³⁻¹⁸, Molecular Beam Epitaxy (MBE)¹⁹⁻²¹, Halide Vapor Phase Epitaxy (HVPE)^{22, 23}, and LPCVD²⁴⁻²⁶ has accelerated the development of β-Ga₂O₃ power devices. This progress in β-Ga₂O₃ epitaxy have directly enabled the development of high-performance vertical and lateral devices including trench Schottky barrier diodes (SBDs)²⁷⁻³⁰, trench MOSFETs^{31,32}, and FinFETs^{33, 34}. In β-Ga₂O₃ vertical devices, where p-type doping is inherently absent, the use of confined and scaled 3D geometries such as vertical fins, mesas, and trenches is essential for controlling current flow and managing electric field distribution. However, the ability to reliably fabricate such high-aspect-ratio 3D structures hinges on achieving controllable, anisotropic, and damage-free etching of β-Ga₂O₃. Conventional dry etching approaches, including inductively coupled plasma etching with BCl₃/Cl₂, offer vertical profiles but are known to induce substantial plasma damage, including oxygen vacancy formation, stoichiometric deviation, and deep-level trap generation^{35, 36}. These effects can significantly degrade interface quality and device performance, lowering breakdown voltages and Schottky barrier heights, while increasing leakage and carrier scattering³⁷⁻⁴⁰. To mitigate these effects, different wet chemical etching methods using hot phosphoric acid (H₃PO₄), hydrofluoric acid (HF), potassium hydroxide (KOH), or tetramethylammonium hydroxide (TMAH), have been explored as plasma-free approaches to minimize surface damage during β-Ga₂O₃ processing⁴¹⁻⁴⁴. These methods offer smooth etched surfaces and low defect densities, but are typically isotropic, lack orientation selectivity, and pose challenges for fabricating vertical, high-aspect-ratio structures. Metal-assisted chemical etching (MacEtch) has also been employed to fabricate submicron-scale fin structures^{33, 34, 45-47}, achieving aspect ratios exceeding 40:1 with smooth sidewalls and low interface trap densities (~2.7×10¹¹ cm⁻²eV⁻¹), which have enabled high-performance devices such as ultra-low-hysteresis FinFETs^{33, 34}. However, challenges remain including its relatively low etch rates (~1-4 nm/min), and reduced Schottky barrier heights due to surface oxygen loss and reconstruction^{46, 47}. More recently, HCl-based dry etching in HVPE systems enables anisotropic, plasma damage-free etching of β-Ga₂O₃, primarily through the formation of volatile gallium chloride species with high vapor pressures⁴⁸⁻⁵³. In addition, forming gas-based thermal etching in tube furnace systems has also been demonstrated for Ga₂O₃ etching⁵⁴. Recently, etching approaches in reactor systems such as MBE and MOCVD, utilizing atomic Ga flux^{30, 55, 56} or precursors such as triethylgallium (TEGa)⁵⁷ or tert-butyl-chloride (TBC1)⁵⁸, have demonstrated facet-selective etching via the formation of volatile gallium suboxide or chloride species. While these approaches demonstrate anisotropic etching through gas-phase reactions, the use of a solid-source gallium configuration within a low-pressure chemical vapor deposition (LPCVD) environment, in which etching is governed by carrier-gas-mediated transport and thermally driven surface reactions within a unified process platform, provides a distinct processing framework for controlled and scalable β-Ga₂O₃ etching.

### SUMMARY OF THE INVENTION

A plasma-free in situ etching technique for gallium oxide (Ga₂O₃) is disclosed, wherein the etching is performed within a low-pressure chemical vapor deposition (LPCVD) reactor using a solid-source metallic gallium (Ga) under a controlled carrier-gas-mediated transport environment. The method is based on thermally activated generation of gallium vapor from a solid source, followed by gas-phase transport and diffusion through a low-pressure ambient to the substrate surface, enabling a coupled vapor transport and surface-reaction-controlled etching process. The etching proceeds through formation and continuous removal of volatile gallium suboxide species, resulting in controlled, anisotropic etching of β-Ga₂O₃. The process allows precise tuning of etch characteristics through adjustment of reactor pressure, carrier gas flow, thermal profile, and source-to-substrate spacing within the LPCVD system.

In one implementation, etching behavior was systematically studied on (2̅01) β-Ga₂O₃ films and patterned (010) β-Ga₂O₃ substrates as a function of temperature (1000-1100 °C), Ar carrier gas flow (80-400 sccm) and Ga source-to-substrate distance (1-5 cm). The process exhibits vapor transport-and surface-reaction-limited behavior, with etch rates reaching a maximum of ~2.25 μm/hr on (010) substrates at 1050 °C and 2 cm spacing. Etch rates decrease sharply with increasing source-to-substrate distance due to reduced Ga vapor availability, while elevated temperatures enhance surface reaction kinetics through increased Ga reactivity and suboxide formation, leading to an enhanced etch rates. In-plane anisotropy studies using radial trench patterns reveal that the (100) orientation produces the most stable etch front, characterized by smooth, vertical sidewalls and minimal lateral etching, consistent with its lowest surface free energy. In contrast, orientations such as (101), which possess higher surface energy, exhibit pronounced lateral etching and micro-faceting. As the trench orientation progressively deviates from (100), lateral etching increases. Facet evolution is observed between (100) and (1̅02), where stepped sidewalls composed of alternating (100) and (1̅02) segments progressively transition into a single inclined facet, which stabilizes along (100) or (1̅02) depending on the trench orientation. The (100)-aligned fins exhibit minimal bottom curvature, while (201)-aligned structures display increased under-etching and trench rounding. Accordingly, the disclosed LPCVD-based in situ etching process enables plasma-free, orientation-dependent, and controllable etching of β-Ga₂O₃. The process is suitable for fabrication of high-aspect-ratio three-dimensional structures, including fins, mesas, and trenches, for use in β-Ga₂O₃-based electronic and power device applications.

In this invention, we demonstrate such an approach by employing metallic Ga in a LPCVD system to enable process-compatible, scalable, and damage-free etching of β-Ga₂O₃. The use of solid Ga, together with inert gas ambient and plasma-free conditions, eliminates the need for organometallic precursors and complex equipment, offering a low-cost, practical and integration-friendly route for fabricating high-quality β-Ga₂O₃ structures. Notably, LPCVD growth system has also been established as a promising platform for developing thick β-Ga₂O₃ films, with recent reports demonstrating high growth rates and excellent electronic transport properties^{24, 25}, including controllable carrier density, promising electron mobility and low background carrier concentration. These combined capabilities position LPCVD as a versatile processing environment for both high-quality growth and anisotropic patterning of β-Ga₂O₃.

### BRIEF DESCRIPTION OF THE DRAWINGS

These and other features, aspects, and advantages of the present invention will become better understood with reference to the following description, appended claims, and accompanying drawings where:

FIG. 1 shows a schematic of LPCVD-based in-situ etching of β-Ga₂O₃, where Ga adatoms selectively react with exposed β-Ga₂O₃ surfaces to form volatile GazO sub-oxide, enabling anisotropic, plasma-free etching through SiO₂ mask-defined regions;

FIG. 2 shows vertical etch rate of (2̅01) β-Ga₂O₃ films and patterned (010) β-Ga₂O₃ substrates as a function of (a) Ga source-to-substrate distance at various temperatures, (b) substrate temperature for both orientations at fixed distance of 2 cm and Ar flow of 200 sccm, (c) substrate temperature for (010) β-Ga₂O₃ at fixed distance of 2 cm and Ar flow of 200 sccm, and (d) Ar carrier gas flow for (010) B-Ga₂O₃ at a distance of 2 cm and temperature of 1050 °C;

FIG. 3 shows at (a) Tilted top-view FESEM image (~60° tilt) of a radial spoke-wheel trench pattern etched into a (010)-Ga₂O₃ substrate, with trenches aligned along various in-plane crystallographic directions; and (b-1) Corresponding high-magnification sidewall SEM images showing orientation-dependent variations in sidewall morphology;

FIG. 4 shows a polar plot of lateral-to-vertical etch rate ratios (rₗᵥ) measured on (010) β-Ga₂O₃ etched at 1000 °C and 1050 °C for one hour, where the plot illustrates strong in-plane anisotropy, with the (100) and (1̅01) directions exhibiting the lowest fiv values, indicative of highly anisotropic etching;

FIG. 5 shows at (a) Tilted FESEM image showing progressive sidewall roughness on (010) β-Ga₂O₃ trenches oriented at increasing angles from the (100) plane; (b) Top-view SEM highlighting the difference between the smooth sidewall along (100) and the stepped sidewall observed along the (6̅01) plane; (c-h) High-magnification SEM images showing stepped facet evolution, with segments composed of alternating (100) and (1̅02) facets; (i) Schematic representation of the sidewall geometry illustrating the angular transition from vertical (100) to inclined (1̅02) facets as the trench orientation rotates away from (100);

FIG. 6 shows at (a-d) Tilted FESEM images of etched trench arrays oriented along different crystallographic directions on (010)-Ga₂O₃ substrates, showing variation in fin width and sidewall morphology; (e) AFM line scans of trench profiles corresponding to each direction, illustrating sharp fin top edges and varying degrees of trench bottom curvature as a function of sidewall orientation;

FIG. 7 shows at (a) Schematic cross-section of the quasi-vertical Schottky barrier diode (SBD) fabricated using LPCVD grown (2̅01) β-Ga₂O₃ film on a 6° miscut c-plane sapphire substrate. The device features a three-layer epitaxial stack: a 1.05 um unintentionally doped (UID) buffer layer, a 2.10 um thick n⁺ β-Ga₂O₃ contact layer (N_{d}=1×10¹⁹ cm⁻³), and a 3.15 μm β-Ga₂O₃ drift layer (N_{d}=2.1×10¹⁷ cm⁻³). Plasma-free LPCVD etching was used to etch 3.6 μm into the β-Ga₂O₃ drift layer for mesa isolation and to expose the n⁺ layer for anode contact formation; (b) Tilted (60° tilt) Cross-sectional FESEM image showing the etch sidewall profile with an etch depth of 3.6 μm; (c) AFM line scan along the AA′ cutline over etched mesa region confirming the ~60°sidewall inclination and an etch depth of 3.6 μm; and (d) Step by-step fabrication process flow including LPCVD growth, in situ etching, and metallization steps for device realization;

FIG. 8 shows a fabrication process flow for planar and mesa-terminated β-Ga₂O₃ Schottky barrier diodes; where (a) A 100 nm thick SiO2 hard mask is deposited by PECVD and patterned by photolithography to define the mesa-etch regions; (b) Ga-assisted LPCVD etching is performed through the SiO2 openings to create a recessed mesa structure with a depth of 8.4 um in selected regions of the wafer, while adjacent regions remain unetched for planar devices; (c) The SiO2 mask is removed after etching by using BOE; and (d) Ti/Au ohmic contacts are formed on the backside followed by rapid thermal annealing at 470 °C for 1 min, after which Ni/Au Schottky contacts are deposited on the front side; and

FIG. 9 shows a process flow for fabricating quasi-vertical β-Ga₂O₃ Schottky barrier diodes on c-plane sapphire using an all-LPCVD growth and etching platform; where (a) As-grown β-Ga₂O₃ epi-stack consisting of a 3.15 μm n drift layer (N_{D}≈2.1×10¹⁷ cm⁻³), a 2.10 μm heavily doped n+layer (N_{D}≈1×10¹⁹ cm⁻³), and a 1.05 μm unintentionally doped buffer on sapphire; (b) Deposition and patterning of a 100 nm PECVD SiO₂ hard mask for mesa definition; (c) Ga-assisted LPCVD etching under oxygen deficient conditionso recess the drift layer and expose the underlying n⁺ layer between mesas; (d) Removal of the SiO₂ hard mask in buffered oxide etch; (e) Deposition of a conformal PECVD SiO₂ passivation layer and patterning of contact windows; and (f) Final device structure with Ni/Au Schottky anode on the mesa top and Ti/Au ohmic cathodes contacting the exposed n⁺ layer, forming a quasi-vertical current path through the drift region.

### DESCRIPTION OF THE PREFERRED EMBODIMENT

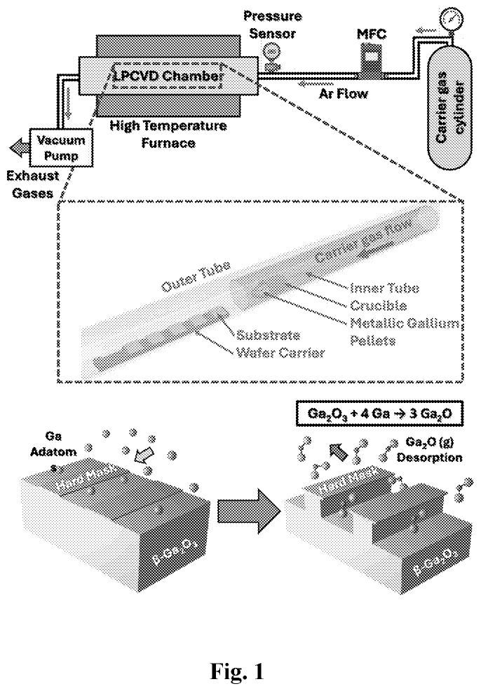

A schematic of the LPCVD-based in-situ etching system used in this study for β-Ga₂O_{3 3} surface patterning is illustrated in FIG. 1. The process was carried out in a custom-built horizontal LPCVD chamber, where etching is enabled by a thermally driven suboxide reaction between β-Ga₂O₃ and solid-source metallic Ga under an oxygen-deficient environment. The overall chemical reaction is expressed as: 4 Ga(s)+Ga₂O₃(s)→3 Ga₂O (g). This reaction results in the formation of volatile Ga₂O, which is continuously removed by the vacuum system. Argon (99.9999% purity) was employed as the carrier and purge gas. High-purity (99.99999%) gallium pellets served as the solid etchant source, placed upstream relative to the substrate holder inside the chamber. The LPCVD chamber was ramped up from room temperature to the target etching temperature at a ramp rate of 10 °C/min, maintained at that temperature for one hour, which was defined as the etching duration, followed by cooling down to room temperature. The etching experiments were performed at temperatures ranging from 1000 °C to 1100 °C, under system pressures of 0.5 to 2.1 Torr corresponding to argon flow rates between 80 and 400 sccm. During the process, both the Ga source and substrate holder were maintained at the same temperature. Two types of samples were investigated: LPCVD-grown (2̅01) β-Ga₂O₃ films grown on 6° off-axis c-sapphire substrates, as reported in our earlier work²⁴, and Fe-doped (010) β-Ga₂O₃ substrates patterned with SiO₂ hard masks. The masks were fabricated by depositing a 100 nm-thick plasma-enhanced chemical vapor deposition (PECVD)-grown SiO₂ layer, followed by optical lithography to define window openings. Prior to the etching, all samples were cleaned sequentially with acetone, IPA, and DI water, followed by nitrogen drying. The Ga source-to-substrate distance was systematically varied between 1 and 5 cm to investigate its influence on etch rate and uniformity. During etching, Ga vapor diffuses toward the substrate surface, selectively reacts with exposed β-Ga₂O₃ regions and forms volatile Ga₂O suboxide. Regions protected by the SiO₂ mask remain unetched, enabling precise pattern transfer. After etching, the SiO₂ mask was removed using a diluted buffered oxide etchant (BOE, 1:50), and the etched structures were characterized by field emission scanning electron microscopy (FESEM) (JEOL JSM 7401F) and atomic force microscopy (AFM) (Park XE-100). Etch depths and sidewall profiles were extracted from FESEM cross-sections and AFM surface line scans to determine etch rates and anisotropy.

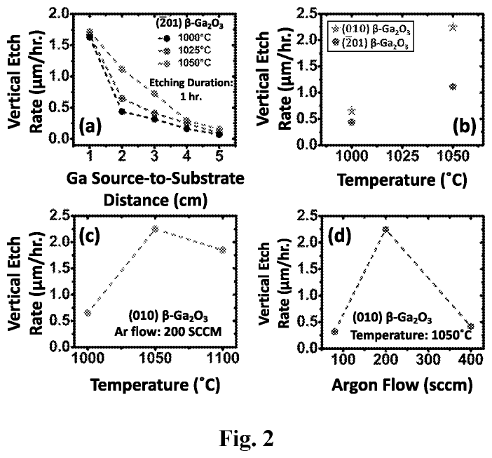

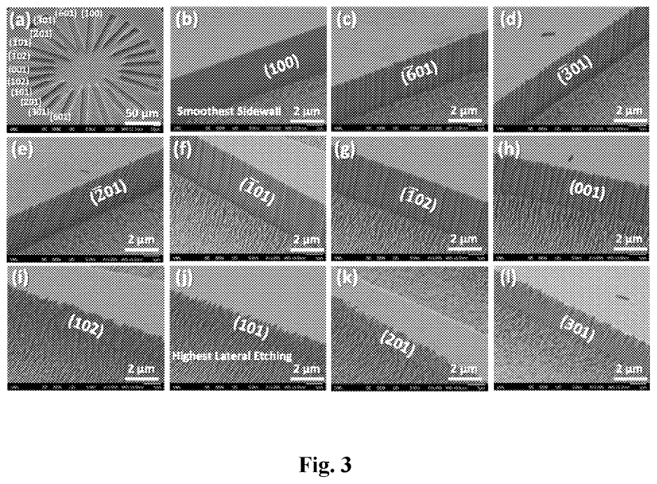

FIG. 2 presents a comprehensive assessment of vertical etch rates in β-Ga₂O₃ as a function of Ga source-to-substrate distance, substrate temperature, and argon flow rate. As shown in FIG. 2 at inset (a), etch rates for (2̅01)-oriented samples exhibit a strong dependence on both distance and temperature. At each temperature, the etch rate peaks when the substrate is closest to the Ga source (1 cm) and decreases steadily with increasing distance due to reduced Ga vapor availability and gas-phase transport losses. For any given source-to-substrate distance, the etch rate increases with temperature, indicating the role of thermally activated surface reaction kinetics and enhanced Ga₂O desorption. This temperature-driven increase is most evident in the intermediate spacing regime (2-3 cm), where both Ga delivery and surface reactivity combinedly influence the overall etch rate. However, at the shortest distance (1 cm), where Ga vapor is already abundant, the effect of temperature is less pronounced, suggesting that the surface may be saturated with Ga and that the process is limited by byproduct desorption from the surface or reaction kinetics. Temperature-dependent behavior is further explored in FIG. 2 at insets (b) and (c) for both (2̅01) and patterned (010)β-Ga₂O₃, confirming consistent etch rate enhancement from 1000 °C to 1050 °C. Notably, the etch rate for (010) β-Ga₂O₃ reaches a maximum of ~2.25 μm/hr at 1050 °C, but slightly declines at 1100 °C, possibly due to parasitic gas phase reactions or Ga depletion at the surface at elevated temperature. Similarly, increasing the argon flow rate improves etch rate up to 200 sccm by enhancing Ga vapor transport as shown in FIG. 2 at inset (d), but further increase to 400 sccm leads to a significant drop, likely due to the Ga dilution and reduced residence time near surface. FIG. 2 at inset (b) compares the temperature-dependent etch rates of (201)-oriented and patterned (010) β-Ga₂O₃ at a fixed Ga source-to-substrate distance of 2 cm and Ar flow rates of 200 sccm. Across the entire temperature range, the (010) orientation consistently exhibits higher etch rates than (2̅01). This difference is attributed to the crystallographic anisotropy of β-Ga₂O₃, where the (010) surface has higher surface energy than (2̅01) and greater chemical reactivity toward Ga-induced suboxide formation⁵⁹. FIG. 3 investigates the in-plane anisotropy of LPCVD etching on (010) β-Ga₂O₃ by evaluating the sidewall profiles of trenches patterned in multiple crystallographic directions. A radial spoke-wheel pattern, shown in FIG. 3 at inset (a), was used to define trenches along different in-plane directions. The etching was performed at 1050 °C for one hour using Ar flow rate of 200 sccm. FIG. 3 at insets (b) (1) present high-magnification SEM images of the etched sidewalls corresponding to each crystallographic direction after mask removal. These results reveal significant variation in sidewall roughness, verticality, and lateral etch behavior as a function of trench orientation, indicating the anisotropic etch response driven by the monoclinic β-Ga₂O₃ crystal structure. Among all orientations, the trench aligned along the (100) sidewall plane (FIG. 3 at inset (b)) exhibits the smoothest and most vertical sidewalls, with minimal roughness and well-defined (100) faceting. This observation aligns well with density functional theory predictions⁵⁹ and previous experimental etching studies^{49, 55} that identify the (100) surface as having the lowest surface energy and the highest stability under etching conditions.

This low reactivity promotes directional, layer-by-layer removal without excessive lateral undercut, making (100) the most favorable orientation for high-fidelity trench fabrication. In contrast, trenches oriented along planes such as (102), (101), (201) and (301) (FIG. 3 at insets (i)-(1)) exhibit pronounced lateral etching and sidewall roughening. Among all orientations, (101) shows the most lateral undercut, indicating it is one of the least stable directions during etching. This behavior is consistent with its highest surface energy and reduced thermodynamic stability as reported by Schewski et al.⁵⁹. Such energetically unfavorable planes are more reactive and less capable of maintaining vertical, smooth sidewalls during anisotropic etching processes. This observation also aligns with experimental findings from HCl-based dry etching in HVPE systems, where the (101) sidewalls on (010) β-Ga₂O₃ substrates exhibited the highest lateral etch rates 49. Intermediate trench orientations, including (6̅01), (3̅01), (2̅01), (1̅01), (1̅02), and (001) (FIG. 3 at insets (c)-(h)), show partial preservation of verticality but with clear evidence of stepped or striped sidewall features. These morphologies arise from the formation of mixed facets and step bunching during the etching, as the system attempts to minimize local surface energy through facet rearrangement, as discussed in more detail in subsequent sections. The (001) sidewall (FIG. 3 at inset (h)), despite being commonly used for epitaxy, also shows sidewall roughness, likely due to its higher surface energy compared to (100), though less than that of (101) or (102) facets⁵⁹. Overall, the pronounced anisotropy in sidewall morphology across all in-plane directions indicates that the (100) orientation yields the most stable and vertical etch front, while orientation such as (101) is more prone to lateral etching and sidewall roughening due to their higher surface energy and reduced thermodynamic stability, as further corroborated by quantitative analysis of lateral etch rates.

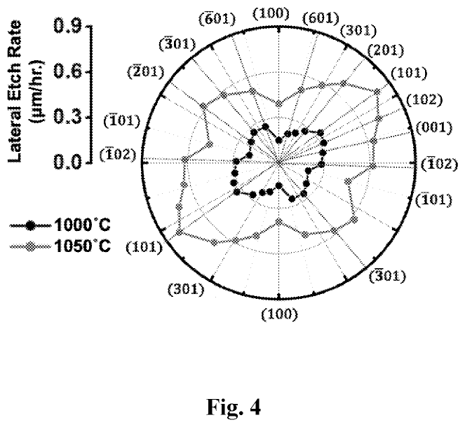

FIG. 4 presents a polar plot of lateral etch rates extracted from spoke-patterned trench arrays etched into (010) β-Ga₂O₃ substrates at 1000 °C and 1050 °C. The lateral etch rate, defined as the amount of trench broadening beyond the original mask-defined width, is plotted as a function of in-plane crystallographic orientations, offering a quantitative measure of the anisotropy in sidewall etching behavior. The plot reveals that lateral etch rates is strongly orientation dependent. Trenches aligned along the (100) and (1̅01) orientations consistently exhibit the lowest and second lowest lateral etching at both temperatures, respectively, indicating highly anisotropic, vertical profiles, correlating with their low surface energies. Similar trends have also been reported for HCl-based etching in HVPE system⁴⁹. In contrast, orientations involving (201), (101), (102) and (001) exhibit much higher lateral etch rates across both temperatures, with (101) demonstrating the most pronounced lateral broadening among all orientations. These orientations expose high-energy surfaces that are more susceptible to isotropic attack and sidewall roughening, consistent with previous reports on HCl-based and MBE etching of β-Ga₂O3, where such planes were found to degrade etch profile fidelity due to increased reactivity^{49, 55}. When comparing the two temperatures, 1050 °C etching results in increased lateral etch rates for all orientations relative to 1000 °C. This trend suggests that higher substrate temperatures enhance both Ga transport and surface reaction kinetics, thereby accelerating the formation and desorption of volatile Ga₂O species. While elevated temperatures promote deeper vertical trench propagation, as also evidenced in FIG. 2 at inset (b) for both (201) and (010) β-Ga₂O₃ orientations, they concurrently increase the reactivity of exposed surfaces. As a result, less thermodynamically stable crystal planes become more susceptible to isotropic etching, leading to enhanced lateral broadening and reduced etch anisotropy in those directions.

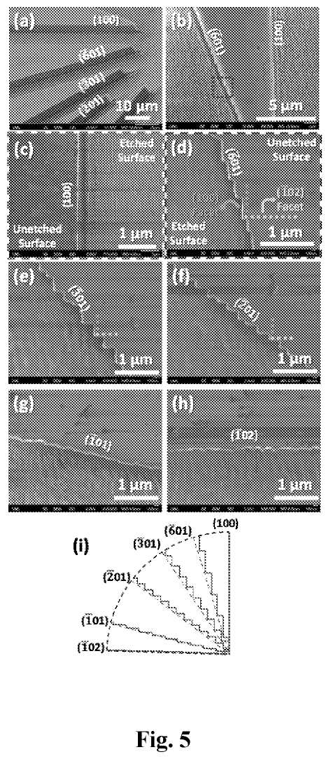

FIG. 5 provides high-resolution SEM images highlighting the evolution of sidewall faceting in trenches etched along progressively rotated in-plane directions on the (010) β-Ga₂O₃ surface. While trenches aligned along the (100) orientation maintain smooth, vertical sidewalls with abrupt terminations, other directions such as (6̅01), (3̅01), and (2̅01) exhibit visibly rougher sidewalls and evidence of stepped micro faceting as shown in FIG. 5 at insets (a) and (b). A closer inspection of the (100) trench edge (FIG. 5 at inset (c)) reveals smooth and vertical sidewalls with relatively flat trench bottom, consistent with its low lateral etch rates and anisotropic behavior. However, as the trench direction rotates toward the (102) orientation, a clear transformation in sidewall morphology is observed across FIG. 5 at insets (d)-(h). For instance, the (6̅01)-oriented trench (FIG. 5 at inset (d)) displays a mixed-facet sidewall, composed of alternating (100) and (102) facets, which intersect at approximately 90°, consistent with the crystallographic relationship between these planes in monoclinic β-Ga₂O₃. These step-like features suggest a local surface reconstruction during etching, where unstable or higher-energy orientations such as those exposed in off-axis directions evolve into combinations of lower-energy facets to reduce the system's overall surface energy. As the trench orientation rotates away from (100) toward intermediate directions such as (301) and (201) (FIG. 5 at inset (e) and (f)), the sidewalls exhibit progressively rougher morphologies characterized by stepped or scalloped features. Notably, the vertical segments associated with (100) facets become shorter, while the horizontal segments likely corresponding to (102) facets increase in length. This shift in facet proportion suggests persistent surface instability and an ongoing transition between competing low-energy planes, reflecting the system's attempt to minimize surface energy in the absence of alignment with a single dominant etch-stable orientation. Interestingly, as the trench alignment approaches (102) As shown in FIG. 5 at inset (h), the sidewall transitions into a more uniform inclined facet with reduced step formation compared to intermediate orientations, suggesting that (102) appears to be a relatively stable etch direction, capable of maintaining uniform surface propagation without decomposing into sub-facets. This behavior is consistent with previous observations during HVPE homoepitaxial growth of (001) Bβ-Ga₂O₃, where (100) and (102) planes were reported to form stable step terraces due to their lower surface energies 60. This progressive change is captured schematically in FIG. 5 at inset (i), which illustrates how the (100) facet initially dominates but is gradually replaced by the inclined facet as the trench orientation rotates. The evolution from mixed-facet to single-facet morphology supports a thermodynamically driven relaxation process, where surface energy minimization governs the final sidewall configuration.

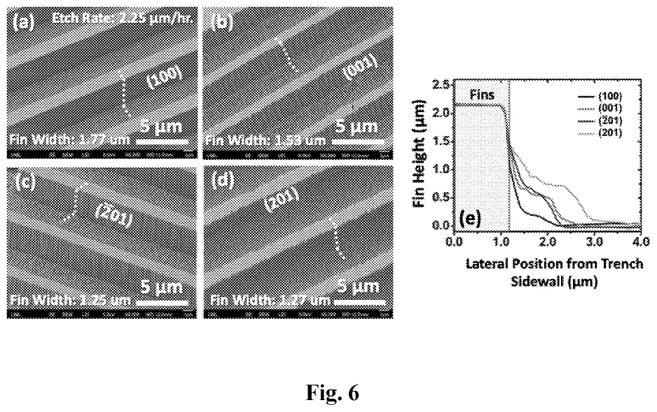

FIG. 6 evaluates the impact of crystallographic orientation on the trench geometry and fin profile resulting from LPCVD Ga-based etching, performed at 1050 °C for one hour using Ar flow of 200 sccm. FIG. 6 at insets (a)-(d) present tilted SEM images of etched trench arrays aligned along the (100), (001), (2̅01), and (201), respectively. While all trenches reach comparable vertical depths (~2.25 μm at 1050 °C), distinct differences in fin width and sidewall morphology are apparent depending on orientation. The (100)-aligned trenches (FIG. 6 at inset (a)) exhibit the most well-defined geometry, featuring sharp, vertical sidewalls with minimal lateral broadening and the wide fin width (~1.77 μm), in line with its thermodynamically stable etch front observed in FIGS. 3 and 5. In contrast, fins formed along (2̅01) and (201) (FIG. 6 at insets (c)-(d)) display significant lateral narrowing (fin widths ~1.25-1.27 μm), reflecting increased under-etching and rougher sidewalls consistent with the facet instabilities previously observed. This orientation-dependent behavior is further supported by the comparative trench profiles shown in FIG. 6 at inset (e), obtained via AFM line scans across all four directions. The trench with (100) sidewalls exhibits the steepest profile with a relatively flat trench bottom, indicating strong anisotropic vertical etching and minimal lateral deviation. By contrast, trenches aligned with (201) exhibit increased bottom curvature, a signature of enhanced sidewall erosion and reduced etch directionality. Intermediate cases, such as (001) and (2̅01), fall between these two, displaying modest undercut and slight trench bottom rounding. This curvature trend mirrors previous findings in Ga-assisted MBE etching studies⁵⁵, where bottom rounding was attributed to limited Ga delivery at the trench base and surface reflow during suboxide formation. While AFM measurements may introduce slight convolution effects due to tip geometry in the immediate vicinity of steep sidewalls, the overall trench profile trends, particularly the observed bottom curvature, remain consistent for comparative analysis and are in good agreement with the sidewall morphology observed by FESEM across orientations.

In summary, the present invention discloses a low-pressure chemical vapor deposition (LPCVD)-based in situ etching process for gallium oxide (Ga₂O₃) utilizing a solid-source metallic gallium under oxygen-deficient, carrier-gas-mediated conditions. The disclosed process enables plasma-free, thermochemically driven etching through formation and continuous removal of volatile gallium suboxide species, thereby providing a controllable and scalable etching technique that preserves structural and chemical integrity of the gallium oxide material. The invention demonstrates that etching behavior can be precisely controlled through adjustment of process parameters including temperature, carrier gas flow rate, chamber pressure, and source-to-substrate spacing. The process exhibits both vapor-transport-limited and surface-reaction-limited regimes, enabling tunable etch rates and anisotropy. Furthermore, the method provides crystallographic orientation-dependent etching, allowing selective formation of stable sidewall geometries, including vertical and inclined facets, without inducing plasma-related damage or stoichiometric degradation. The disclosed process enables fabrication of high-aspect-ratio three-dimensional Ga₂O₃ structures, including fins, mesas, trenches, and field-termination geometries, with improved surface quality and reduced defect generation compared to conventional plasma-based or wet chemical etching techniques. The anisotropic etching behavior further allows orientation-selective patterning, enabling precise control of device-relevant geometries for electric field management and current confinement. Additionally, the LPCVD-based approach provides compatibility with integrated epitaxial growth processes, enabling a unified growth and etching platform for Ga₂O₃ device fabrication. The ability to perform plasma-free etching within the same LPCVD environment as epitaxial growth reduces process complexity and enhances manufacturability for wafer-scale applications. Accordingly, the invention establishes a scalable, damage-free, and process-compatible etching framework for Ga₂O₃, suitable for fabrication of advanced electronic and power devices, including but not limited to Schottky barrier diodes, field-effect transistors, and other high-voltage or high-frequency architectures. The disclosed method provides a distinct and advantageous approach for patterning ultrawide bandgap semiconductor materials while maintaining material quality and enabling high-performance device integration.

### Example 1

An example implementation of the disclosed low-pressure chemical vapor deposition (LPCVD)-based plasma-free gallium oxide etching process is provided. In this example, quasi-vertical β-Ga₂O₃ Schottky barrier diodes are fabricated on c-plane sapphire substrates using an integrated LPCVD process flow comprising β-Ga₂O₃ epitaxial growth and solid-source gallium-assisted in situ etching. A multilayer β-Ga₂O₃ epitaxial structure is grown on an insulating sapphire substrate and selectively etched in an LPCVD reactor using solid-source metallic gallium under oxygen-deficient, inert gas conditions to define mesa-isolated device regions. The LPCVD etching step removes exposed-Ga₂O₃ material while preserving the structural and chemical integrity of the etched surfaces. The resulting Schottky barrier diodes demonstrate rectifying current-voltage behavior, uniform drift-layer doping, stable temperature-dependent operation, and reverse-blocking capability. This example demonstrates that LPCVD-based solid-source gallium etching can be integrated with LPCVD-grown β-Ga₂O₃ epitaxy to fabricate functional power electronic devices using a plasma-free process flow. A 6.3 μm thick (2̅01) oriented β-Ga₂O₃ epitaxial layer structure was grown on c-plane sapphire with 6° miscut, comprising a moderately Si-doped (2.1×10¹⁷ cm⁻³) 3.15 μm thick drift layer and a heavily doped (1×10¹⁹ cm⁻³) contact layer on an unintentionally doped buffer layer. Mesa isolation was achieved via Ga-assisted plasma-free LPCVD etching, producing a ~60° inclined mesa sidewalls with an etch depth of 3.6 μm. The fabricated SBDs exhibited excellent forward current-voltage characteristics, including a turn-on voltage of 1.22 V, an ideality factor of 1.29, and a Schottky barrier height of 0.83 eV. The minimum differential specific on-resistance was measured to be 8.6 mΩ·cm², and the devices demonstrated high current density capability (252 A/cm² at 5 V).

Capacitance-voltage analysis revealed a net carrier concentration of 2.1×10¹⁷ cm⁻³, uniformly distributed across the β-Ga₂O₃ drift layer. Temperature-dependent J-V-T measurements from 25 °C to 250 °C revealed thermionic emission-dominated transport with strong thermal stability. The Schottky barrier height increased from 0.80 eV to 1.16 eV, and the ideality factor rose modestly from 1.31 to 1.42 over this temperature range. Reverse leakage current remained low, increasing from ~5×10⁻⁶ A/cm² at 25 °C to ~1×10⁻⁴ A/cm² at 250 °C, with the Iₒₙ/I_{off} ratio decreasing from ~1×10⁷ to 5×10⁵. The devices achieved breakdown voltages ranging from 73 V to 100 V, corresponding to parallel-plate electric field strengths of 1.66-1.94 MV/cm. This example demonstrates that LPCVD-based solid-source gallium etching can be integrated with LPCVD-grown β-Ga₂O₃ epitaxy to fabricate functional power electronic devices using a plasma-free process flow.

### LPCVD Growth of β-Ga₂O₃ Epitaxial Stack

The (2̅01) β-Ga₂O₃ epitaxial layers were grown in a custom-designed LPCVD chamber on c-plane sapphire substrates with a 6° miscut. This intentional off-axis orientation facilitates step-flow growth and suppresses defect formation, enabling high crystalline quality of the epitaxial film^{25, 61, 62}. Prior to growth, the substrate was sequentially cleaned with acetone, isopropyl alcohol (IPA), and deionized (DI) water, followed by nitrogen blow-drying. Ultra-high purity argon (99.9999%) was used as both the carrier and purge gas, while oxygen (99.999%) and metallic gallium pellets (99.99999%) served as the oxygen and gallium sources, respectively. Silicon tetrachloride (SiCl₄) was introduced as the n-type Si dopant, with flow rates adjusted to achieve desired doping concentrations. The growth was carried out at a substrate temperature of 1000 °C and a chamber pressure of ~1.5 Torr, with the substrate placed 7 cm from the gallium source. The epitaxial stack consisted of three distinct layers with a total thickness of 6.3 μm. Growth began with a 10-minute unintentionally doped (UID) β-Ga₂O₃ buffer layer (1.05 μm thick) grown without any SiCl₄ flow. This was followed by a 20-minute growth of n⁺ Si-doped B-Ga₂O₃ layer (2.10 μm thick) using a SiCl₄ flow rate of 0.5 sccm to achieve a high doping concentration of 1×10¹⁹ cm⁻³, forming the contact layer for the Schottky barrier diode. Finally, the Si doped β-Ga₂O₃ drift layer was grown for 30 minutes using a reduced SiCl₄ flow rate of 0.001 sccm, targeting a doping concentration of 2.1×10¹⁷ cm⁻³and achieving a total thickness of 3.15 μm.

### Plasma-Damage Free Etching of β-Ga₂O₃ using LPCVD

Plasma-free mesa isolation was achieved using our custom-built horizontal LPCVD system, where etching is driven by the thermal reaction between β-Ga₂O³ and upstream metallic Ga vapor in an oxygen-deficient environment. The etch process was conducted at 1050 °C and a pressure of ~1.2 Torr, with the sample placed 2 cm downstream from the solid Ga source. Ultra-high purity argon (99.9999%) was used as the carrier and purge gas. Prior to etching, the samples were cleaned using acetone, IPA, and DI water, followed by nitrogen blow-drying. A 100 nm-thick SiO₂ hard mask was deposited using plasma-enhanced chemical vapor deposition (PECVD) and patterned via optical lithography to expose the regions targeted for etching. The samples were etched for 2 hours and 15 minutes, resulting in a measured etch depth of 3.6 μm, corresponding to an average etch rate of 1.6 μm/hr. This etch depth was intentionally selected to fully remove the drift layer and selectively reach into the n⁺ region, enabling device isolation and providing access to the n⁺ layer for subsequent ohmic contact formation. After etching, the SiO₂ mask was removed using a 1:50 diluted buffered oxide etch (BOE).

### Structural, Surface Morphological, and Chemical Characterization

The surface morphology of the β-Ga₂O₃ epi-stack was characterized using a JEOL JSM-7401F field-emission scanning electron microscope (FESEM) to visualize surface texture and etch profiles, and a Park Systems XE-100 atomic force microscope (AFM) operated in tapping mode to quantify nanoscale roughness. The crystalline structure, phase purity, and orientation of the films were evaluated by high-resolution X-ray diffraction (XRD) using a Rigaku SmartLab diffractometer equipped with a Cu Kα radiation source (λ=1.5418 Å). Wide-angle 20-θω scans and rocking curves (ω-scans) were used to confirm phase purity and determine the out-of-plane crystalline orientation. Raman spectroscopy was carried out using a Horiba LabRam Evolution Raman spectrometer with a 532 nm excitation source to assess phonon modes and verify structural integrity before and after etching. X-ray photoelectron spectroscopy (XPS) measurements were performed using a Thermo Scientific XPS system with a monochromated Al Kα X-ray source (E=1486.6 eV) to analyze chemical composition and bonding states. High-resolution scans of the Ga 3s and O 1s core levels were used to calculate the O/Ga ratio and monitor potential changes in surface chemistry following the LPCVD-based etching process.

### Quasi-Vertical β-Ga₂O₃ Schottky Diode Fabrication

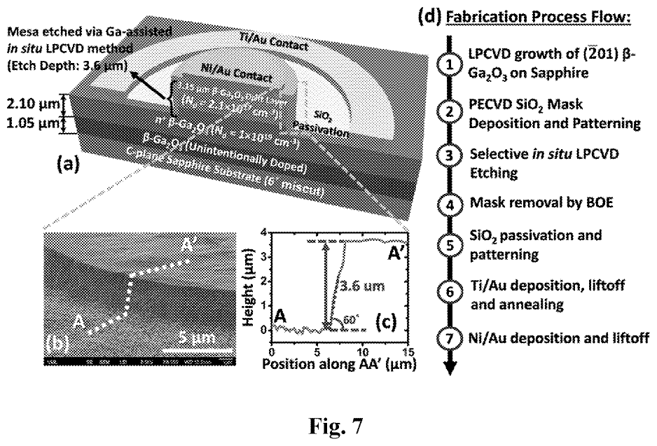

Following mesa isolation by LPCVD Ga-assisted etching, device fabrication was completed using sequential photolithography, passivation, metallization, and annealing steps. First, a 200 nm-thick SiO₂ passivation layer was deposited across the entire wafer surface using PECVD. Photolithography and buffered oxide etch (BOE) were then used to open windows in the SiO₂ layer to define the cathode region. A Ti/Au (20 nm/50 nm) metal stack was deposited by electron-beam evaporation and patterned via lift-off to form the cathode contact on the β-Ga₂O₃ surface surrounding the recessed mesa. This was followed by rapid thermal annealing (RTA) at 470 °C for 1 min in nitrogen ambient to improve metal-semiconductor contact characteristics. Subsequently, a second photolithography step was used to define the anode contact region. Ni/Au (30 nm/50 nm) was deposited via electron-beam evaporation and patterned using lift-off to form the Schottky contact on top of the etched mesa. The final device structure and full fabrication process flow are illustrated in FIG. 7 at insets (a) and (d), with the FESEM and AFM images (FIG. 7 at insets (b) and (c)) confirming an etch depth of 3.6 μm with inclined (~60°) sidewalls. Post-fabrication electrical characterization, including room-temperature and high-temperature (up to 250 °C) Current-Voltage (J-V), Capacitance-Voltage (C-V) and reverse breakdown measurements, was performed using a Keithley 4200A-SCS Semiconductor Parameter Analyzer.

### Example 2

An example implementation of the disclosed LPCVD-based plasma-free gallium oxide etching process is provided for forming deep-mesa field-termination structures in vertical β-Ga₂O₃ Schottky barrier diodes. In this example, a β-Ga₂O₃ epitaxial structure on a native β-Ga₂O₃substrate is selectively etched in an LPCVD reactor using solid-source metallic gallium under oxygen-deficient, inert gas conditions to form a recessed mesa termination around a Schottky contact region. The thermally activated etching method provides a plasma-free route to form deep mesa terminations while maintaining excellent device integrity. The fabricated diodes exhibit ideal forward conduction with a turn-on voltage of 1.14V, a Schottky barrier height (SBH) of 1.15eV, an ideality factor of 1.20, and an on-resistance of 3.72 m 22cm 2 , all closely matching the unetched planar devices. Capacitance-voltage analysis further confirms a uniform carrier concentration of 2×10¹⁶ cm⁻³and an SBH of 1.23eV, indicating stable electrical characteristics after deep mesa formation. Temperature dependent electrical measurements from 25 to 250 °C show stable thermionic-emission transport, with a gradual rise in on-resistance at higher temperatures from phonon-limited mobility. Over this range, the SBH decreases from 1.16 to 1.12eV, while the ideality factor increases from 1.21 to 1.32. The leakage current remains low across the entire temperature range, and the rectification ratio stays above 10⁵ even at 250 °C. Under reverse bias, the diodes exhibit an increase in breakdown voltage from 287 to 500V, confirming the effectiveness of geometric field redistribution achieved by the deep-etched mesa. TCAD simulations corroborate these observations, showing suppression of electric field crowding near the anode edge. This example demonstrates that LPCVD-based solid-source gallium etching can be used to form plasma-free field-termination structures for β-Ga₂O₃ power devices while maintaining device electrical integrity.

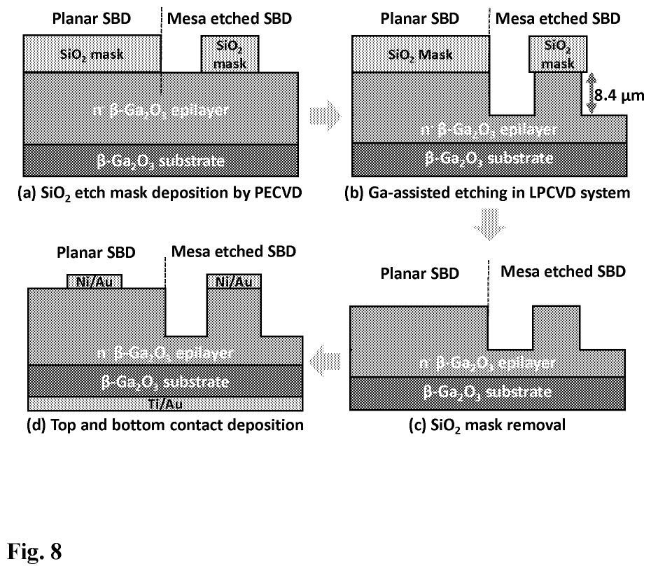

Vertical-Ga₂O₃ SBDs were fabricated on (001) β-Ga₂O₃ epitaxial wafers grown by halide vapor phase epitaxy (HVPE) (Novel Crystal Technology, Inc.). The epi-structure comprised a ~10.8 μm-thick n drift layer (Si-doped, 2×10¹⁶ cm⁻³) grown on a ~625 μm-thick Sn-doped n⁺ substrate (~5.4×10¹⁸ cm⁻³). Edge termination was achieved through plasma-free Ga-assisted LPCVD deep mesa etching. A 100 nm-thick SiO₂ hard mask was deposited by plasma-enhanced chemical vapor deposition (PECVD) and patterned by optical lithography to expose the edge region surrounding the Schottky anode. FIG. 8 shows the complete fabrication flow, including SiO₂ mask deposition and patterning, Ga-assisted mesa etching, mask removal, and final metallization steps. The etching was performed in a custom-built horizontal LPCVD system [60, 61]. High-purity metallic Ga (99.99999%) served as the solid etchant source, and high-purity Ar (99.9999%) was used as the carrier and purge gas. The samples were positioned 2 cm downstream from the Ga source, and the process was carried out at 1050 °C and a chamber pressure of 1.2 Torr. The etch duration of 2.5 hours produced a mesa depth of 8.4 μm, corresponding to an average etch rate of 3.36 μm h⁻¹. After etching, the SiO₂ mask was stripped in buffered oxide etch (BOE). The samples were then rinsed in deionized water and dried in N₂. Following mesa formation, the ohmic contact was first formed on the back side of the n⁺ β-Ga₂O₃ substrate by blanket deposition of Ti/Au (30 nm/100 nm) using electron-beam evaporation, followed by rapid thermal annealing (RTA) at 470 °C for 1 min in N 2 ambient. Subsequently, the Schottky contact was defined on the top surface by depositing Ni/Au (30 nm/100 nm) through a photolithographically patterned lift-off process. During the Ga-assisted LPCVD mesa formation, a lateral etch component of 10 μm was observed beneath the SiO₂ mask. The Schottky anode lithography was therefore aligned relative to the etched mesa geometry, and the contact mask was adjusted accordingly. Because the fabrication is not strictly self-aligned, minor alignment tolerances inherent to the lithography process cannot be completely excluded; however, microscopic inspection indicates that no significant unintended gap or excessive overlap is present between the anode edge and the mesa sidewall. Planar reference diodes without LPCVD mesa etching were fabricated in parallel on the same wafer for direct comparison. In addition, to evaluate the effect of the high-temperature LPCVD mesa process with the SiO₂ mask, planar SBDs were also fabricated on a separate diced piece from the same (001) β-Ga₂O₃ epitaxial wafer that did not undergo the high-temperature processing step. Electrical characterization was performed on a temperature-controlled probe station. Current density-voltage (J-V) and capacitance-voltage (C-V) measurements were obtained using a Keithley 4200A-SCS parameter analyzer.

### Example 3

An example implementation of the disclosed LPCVD-based plasma-free gallium oxide etching process is provided for fabricating β-Ga₂O₃ Schottky barrier diodes suitable for radiation-relevant environments. In this example, B-Ga₂O3 Schottky barrier diodes are fabricated on c-plane sapphire substrates using an LPCVD-grown heteroepitaxial β-Ga₂O₃ structure and solid-source gallium-assisted LPCVD etching for plasma-free mesa definition. The electrical response of Ni/β-Ga₂O₃ Schottky barrier diodes fabricated on c-plane sapphire substrates to high-fluence fast-neutron irradiation is investigated. The β-Ga₂O₃ heteroepitaxial device stack is grown by low-pressure chemical vapor deposition (LPCVD) and comprises a 1.05 μm unintentionally doped buffer, a 2.10 μm n⁺ layer (N_{D}≈1×10¹⁹ cm⁻³), and a 3.15 μm drift layer (N_{D}≈2.1×10¹⁷ cm⁻³), with plasma-free mesa definition achieved using Ga-assisted LPCVD based etching. Prior to irradiation, the devices exhibit a turn-on voltage of 1.20 V, specific on-resistance R_{on,sp}=8.43 mΩ·cm² , ideality factor η=1.32, and a Schottky barrier height of 1.29 eV. Fast-neutron exposure at a 1 MeV equivalent fluence of 1×10¹⁵ n cm² reduces the forward current, increases the turn-on voltage to 2.40 V, and slightly raises R_{on,sp} to 8.85 mΩ·cm² , while the barrier height increases to 1.34 eV and the net donor concentration in the drift layer decreases by ~50 percent to 1.05×10¹⁷ cm⁻³, corresponding to a carrier-removal rate of ~105 cm⁻¹. Temperature-dependent measurements from 25 to 250 °C confirm that thermionic emission remains the dominant transport mechanism and show a systematic suppression of reverse leakage. The breakdown voltage slightly increases from 101 V to 135 V, accompanied by a reduction in the estimated peak electric field from 2.77 to 2.24 MV·cm⁻¹ , consistent with neutron-induced drift-layer compensation. Two-dimensional technology computer-aided design (TCAD) simulations reveal that the electric field becomes more uniformly distributed over a wider depletion region, reducing field crowding at the Schottky edge. This example demonstrates that devices fabricated using the disclosed LPCVD-based solid-source gallium etching process can retain functional diode behavior after neutron exposure, supporting use of the process for β-Ga₂O3 devices intended for space, nuclear, and other radiation-relevant electronic applications.

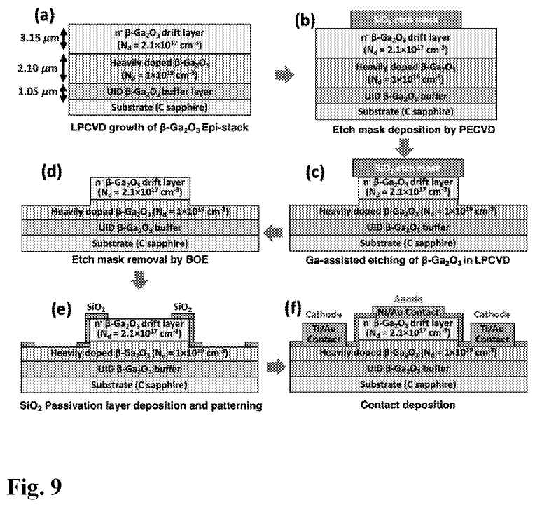

The β-Ga₂O₃ epitaxial heterostructure was grown in a custom horizontal low-pressure chemical vapor deposition (LPCVD) reactor on commercially available c-plane sapphire substrates with a 6° miscut in order to promote step-flow growth and suppress extended defect formation³³. Ultra-high-purity argon served as both carrier and purge gas, while high purity oxygen and solid metallic gallium pellets were used as the O and Ga precursors, respectively. The total reactor pressure during growth was maintained near 1.5 Torr and the substrate temperature was fixed at 1000 °C, with the substrate positioned 7 cm downstream from the gallium source boat. The epitaxial stack consisted of three electrically distinct layers with a total thickness of 6.3 μm as shown in. FIG. 9 at inset (a). Growth started with a 1.05 μm thick unintentionally doped β-Ga₂O₃ buffer layer. This was followed by a 2.10 μm thick heavily doped n⁺ β-Ga₂O₃ layer grown using a SiCl₄ flow of 0.5 sccm to achieve a donor concentration of 1×10¹⁹ cm⁻³, which served as the common contact layer for the vertical quasi-Schottky structure. Finally, a 3.15 μm moderately doped drift layer was deposited by reducing the SiCl₄ flow to 0.001 sccm to achieve a target donor density of 2.1×10¹⁷ cm⁻³.

After epitaxy, mesa isolation and quasi-vertical current path definition were realized using our Ga-assisted LPCVD etching process³⁶. A 100 nm thick SiO₂ hard mask was deposited by plasma enhanced CVD and patterned photolithographically to expose the regions to be recessed. The wafers were then transferred back into the LPCVD reactor, where thermally activated etching proceeded at 1050 °C and 1.2 Torr under oxygen deficient conditions with argon carrier gas and an upstream metallic Ga source. The etch depth was chosen to be 3.6 μm so that the entire 3.15 μm drift layer was recessed within the mesa region and a portion of the underlying n⁺ layer was exposed between mesas. Following mesa formation and removal of the SiO₂ etch mask in a dilute buffered oxide etch (BOE), device fabrication proceeded through sequential dielectric passivation, metallization, and annealing steps to complete the Schottky barrier diode structure.

First, the wafer surface was encapsulated with a conformal SiO₂ passivation layer deposited by plasma enhanced CVD in order to protect the etched sidewalls during subsequent processing and to define the active junction area. Standard optical lithography and SiO₂ etching were then used to open windows in the passivation over the recessed n⁺ regions surrounding the mesa, where ohmic contacts to the heavily doped layer were formed. A Ti/Au metal stack was deposited by electron beam evaporation and patterned using lift-off to define these cathode contacts, followed by rapid thermal annealing at 470 °C for 1 minute in nitrogen ambient to improve contact resistivity. A second photolithography step was employed to open a circular window in the passivation directly above the central drift region at the mesa top, after which Ni/Au was deposited and lifted off to form the Schottky anode electrode. The final layout as shown in FIG. 9 at inset (f) therefore consisted of a Ni/Au anode contacting the drift layer on top of the etched mesa, flanked by Ti/Au cathodes that accessed the underlying n⁺ β-Ga₂O₃ layer on the planar regions. This configuration established a vertical current path from the anode through the drift layer into the n⁺ contact layer and then laterally to the cathode pads, while the sapphire substrate provided electrical isolation. The electrical performance, structural and chemical characteristics of the epi-stack and device platform can be found in our recent report³⁵.

Neutron irradiation of the completed Schottky diodes was performed at the University of Massachusetts Lowell Radiation Laboratory using the Fast Neutron Irradiator (FNI). The FNI provides a fast to thermal neutron flux ratio greater than 4000:1 and, at a reactor power of 1 MW, supplies a 1 MeV equivalent neutron flux of 8×10¹⁰ n cm⁻² s⁻¹ with less than ±20 percent spatial variation across the sample plane. Irradiations were conducted at room temperature under unbiased condition and were timed to achieve a total fluence of 1×10¹⁵ n cm⁻², corresponding to the calibrated 1 MeV equivalent flux of the FNI. After irradiation, the devices were transferred to a temperature-controlled probe station equipped with a resistive heating chuck that allowed stable operation over the full temperature range used in this study. A single electro thermal cycle was performed to examine the temperature dependent evolution of device characteristics following neutron exposure. Current-voltage and capacitance-voltage measurements were collected using a Keithley 4200A SCS semiconductor parameter analyzer at controlled chuck temperatures of 25 °C, 100 °C, 200 °C, and 250 °C. After the final measurement at 250 °C, the devices were allowed to cool naturally to room temperature.

Accordingly, as can be determined from the above, the present patent document discloses a method for selective etching of gallium oxide, comprising: (a) placing a gallium oxide substrate or epitaxial wafer inside a low-pressure chemical vapor deposition (LPCVD) chamber, wherein the gallium oxide is undoped or doped with one or more dopants selected from silicon (Si), tin (Sn), germanium (Ge), magnesium (Mg), nitrogen (N), iron (Fe), other group-IV dopants or combinations thereof; (b) providing a gallium source within or fluidically coupled to the LPCVD chamber; (c) generating gallium vapor from the gallium source under low-pressure conditions; (d) transporting the gallium vapor through a carrier-gas-mediated environment to an exposed surface of the gallium oxide substrate or epitaxial wafer; and (e) etching the exposed surface of the gallium oxide by a thermally activated reaction between gallium and gallium oxide to form volatile gallium suboxide species.

The method may further comprise etching alpha-phase gallium oxide (α-Ga₂O₃), beta-phase gallium oxide (β-Ga₂O₃), kappa-phase gallium oxide (κ-Ga₂O₃), epsilon-phase gallium oxide (ε-Ga₂O₃), gamma-phase gallium oxide (γ-Ga₂O₃), delta-phase gallium oxide (δ-Ga₂O₃), or combinations thereof.

The method may further comprise embodiments wherein the gallium oxide substrate or epitaxial wafer comprises a homoepitaxial gallium oxide layer grown on a native gallium oxide substrate.

The method may further comprise embodiments wherein the gallium oxide substrate or epitaxial wafer comprises a heteroepitaxial gallium oxide layer grown on a foreign substrate.

The method may further comprise embodiments wherein the foreign substrate comprises sapphire, silicon, silicon carbide, gallium nitride, aluminum nitride, diamond, or combinations thereof.

The method may further comprise embodiments wherein the gallium source comprises solid-source metallic gallium positioned inside the LPCVD chamber.

The method may further comprise embodiments wherein the gallium source comprises liquid gallium, solid gallium, gallium vapor, a gallium-containing gas, a gallium-containing precursor, or combinations thereof.

The method may further comprise embodiments wherein the gallium source is positioned upstream from the gallium oxide substrate or epitaxial wafer relative to a carrier gas flow direction.

The method may further comprise embodiments wherein the gallium vapor is transported to the gallium oxide surface by diffusion, convection, carrier gas flow, or combinations thereof.

The method may further comprise embodiments wherein the etching is governed by coupled vapor transport and surface-reaction kinetics.

The method may further comprise embodiments wherein the etching is governed by carrier-gas-mediated transport of gallium vapor under low-pressure conditions.

The method may further comprise embodiments wherein the etching is performed without plasma generation, ion bombardment, or energetic particle exposure.

The method may further comprise embodiments wherein the etching is performed in an oxygen-deficient or oxygen-free environment.

The method may further comprise embodiments wherein the carrier gas comprises argon, nitrogen, helium, neon, or combinations thereof.

The method may further comprise embodiments wherein the carrier gas comprises argon.

The method may further comprise embodiments wherein the thermally activated reaction comprises: 4Ga+Ga₂O₃→3Ga₂O.

The method may further comprise embodiments wherein the volatile gallium suboxide species comprise Ga₂O.

The method may further comprise embodiments wherein the volatile gallium suboxide species are continuously removed by carrier gas flow, vacuum pumping, or both.

The method may further comprise embodiments wherein the LPCVD chamber comprises a horizontal tube reactor.

The method may further comprise embodiments wherein the LPCVD chamber comprises a hot-wall reactor, a cold-wall reactor, a multi-zone reactor, a horizontal quartz tube reactor, or combinations thereof.

The method may further comprise embodiments further comprising forming a mask on the gallium oxide surface before etching.

The method may further comprise embodiments wherein the mask defines one or more exposed regions of the gallium oxide surface to be etched.

The method may further comprise embodiments wherein the mask comprises silicon dioxide (SiO₂), silicon nitride (Si₃N4), aluminum oxide (Al₂O3), hafnium oxide (HfO2), titanium oxide (TiO2), photoresist, metal, or combinations thereof.

The method may further comprise embodiments wherein the mask is deposited by plasma-enhanced chemical vapor deposition, atomic layer deposition, sputtering, metal evaporation, thermal oxidation, low-pressure chemical vapor deposition, or combinations thereof.

The method may further comprise embodiments wherein the mask is patterned by optical lithography, electron-beam lithography, nanoimprint lithography, shadow masking, or combinations thereof.

The method may further comprise embodiments wherein regions protected by the mask remain substantially unetched during the LPCVD etching process.

The method may further comprise embodiments wherein the etching forms a trench, mesa, fin, recess, sidewall, pillar, channel, isolation region, field-termination region, or combinations thereof.

The method may further comprise embodiments wherein the etching forms high-aspect-ratio three-dimensional gallium oxide structures.

The method may further comprise embodiments wherein the etched structures have a lateral dimension from about 10 nm to about 500 μm.

The method may further comprise embodiments wherein the etched structures have a lateral dimension from about 10 nm to about 100 μm.

The method may further comprise embodiments wherein the etched structures have an etch depth from about 50 nm to about 200 μm.

The method may further comprise embodiments wherein the etched structures have an etch depth from about 0.01 μm to about 50 μm.

Additionally, a method for blanket etching of gallium oxide is disclosed, comprising: (a) placing a gallium oxide substrate or epitaxial wafer inside a low-pressure chemical vapor deposition (LPCVD) chamber, wherein the gallium oxide is undoped or doped with one or more dopants selected from silicon (Si), tin (Sn), germanium (Ge), magnesium (Mg), nitrogen (N), iron (Fe), or combinations thereof; (b) generating gallium vapor from a gallium source under low-pressure conditions; (c) transporting the gallium vapor through a carrier-gas-mediated environment to an unmasked gallium oxide surface; and (d) uniformly removing gallium oxide from the unmasked gallium oxide surface through formation and removal of volatile gallium suboxide species.

The method may further comprise embodiments wherein the gallium oxide surface is etched without a patterned mask.

The method may further comprise embodiments wherein the blanket etching is used for surface smoothing, thickness trimming, recess formation, surface preparation, removal of damaged material, or combinations thereof.

The method may further comprise embodiments wherein the etching is performed at a temperature from about 300 °C to about 1500 °C.

The method may further comprise embodiments wherein the etching is performed at a temperature from about 900 °C to about 1150 °C.

The method may further comprise embodiments wherein the etching is performed at a temperature from about 1000 °C to about 1100 °C.

The method may further comprise embodiments wherein the etching is performed at about 1050 °C.

The method may further comprise embodiments wherein the LPCVD chamber pressure is from about 0.1 Torr to about 500 Torr.

The method may further comprise embodiments wherein the LPCVD chamber pressure is from about 0.5 Torr to about 5 Torr.

The method may further comprise embodiments wherein the LPCVD chamber pressure is about 1.2 Torr.

The method may further comprise embodiments wherein the carrier gas flow rate is from about 1 standard cubic centimeter per minute (sccm) to about 50000 sccm.

The method may further comprise embodiments wherein the carrier gas flow rate is from about 80 sccm to about 400 sccm.

The method may further comprise embodiments wherein the carrier gas flow rate is about 200 sccm.

The method may further comprise embodiments wherein a source-to-substrate spacing between the gallium source and the gallium oxide substrate or epitaxial wafer is from about 0.1 cm to about 50 cm.

The method may further comprise embodiments wherein the source-to-substrate spacing is from about 1 cm to about 10 cm.

The method may further comprise embodiments wherein the source-to-substrate spacing is about 2 cm.

The method may further comprise embodiments wherein the etching duration is from about 0.5 minute to about 10 hours.

The method may further comprise embodiments wherein the etching duration is from about 10 minutes to about 5 hours.

The method may further comprise embodiments wherein the etch rate is from about 10 nm/hr to about 20 μm/hr.

The method may further comprise embodiments wherein the etch rate is from about 50 nm/hr to about 3.5 μm/hr.

The method may further comprise embodiments wherein the etch rate reaches about 2.25 μm/hr on a (010) beta-phase gallium oxide (β-Ga₂O₃) substrate.

The method may further comprise embodiments wherein the etch rate reaches about 3.36 μm/hr during deep mesa formation.

The method may further comprise embodiments wherein the etch rate is controlled by adjusting temperature, chamber pressure, carrier gas flow rate, source-to-substrate spacing, gallium source temperature, substrate temperature, etching duration, or combinations thereof.

The method may further comprise embodiments wherein the gallium oxide has a crystallographic orientation comprising (010), (001), (100), (−201), (−102), (201), (101), (301), or combinations thereof.

The method may further comprise embodiments wherein the etching is crystallographically anisotropic.

The method may further comprise embodiments wherein different crystallographic orientations of beta-phase gallium oxide (β-Ga₂O₃) exhibit different vertical etch rates, lateral etch rates, sidewall profiles, or combinations thereof.

The method may further comprise embodiments wherein a (010)-oriented beta-phase gallium oxide (β-Ga₂O₃) surface exhibits a higher etch rate than a (−201)-oriented beta-phase gallium oxide (β-Ga₂O₃) film under otherwise similar conditions.

The method may further comprise embodiments wherein trenches aligned to expose (100)-oriented sidewalls exhibit reduced lateral etching relative to trenches aligned to expose higher-energy sidewall orientations.

The method may further comprise embodiments wherein (100)-oriented sidewalls exhibit smoother or more vertical profiles than sidewalls oriented along (101), (201), (301), or (102).

The method may further comprise embodiments wherein lateral etching increases as a trench orientation deviates from a (100) direction.

The method may further comprise embodiments wherein the etching produces orientation-dependent sidewall faceting.

The method may further comprise embodiments wherein the etching produces sidewall facets comprising (100), (−102), or combinations thereof.

The method may further comprise embodiments wherein sidewalls evolve from stepped sidewalls comprising alternating (100) and (−102) facets into a single inclined facet.

The method may further comprise embodiments wherein trench orientation determines whether a sidewall stabilizes along a (100) facet or a (−102) facet.

The method may further comprise embodiments wherein a (100)-aligned fin exhibits reduced bottom curvature relative to a (201)-aligned etched structure.

The method may further comprise embodiments wherein a (201)-aligned structure exhibits greater under-etching or trench rounding relative to a (100)-aligned structure.

The method may further comprise embodiments wherein crystallographic anisotropy is used to form self-aligned or orientation-selective device structures.

The method may further comprise embodiments wherein orientation-dependent lateral etching is used to control sidewall angle, fin width, mesa geometry, trench shape, field-termination geometry, or combinations thereof.

The method may further comprise embodiments wherein the etched gallium oxide surface is substantially free of plasma-induced damage.

The method may further comprise embodiments wherein the etched gallium oxide surface is substantially free of ion-bombardment-induced lattice disorder.

The method may further comprise embodiments wherein the etched gallium oxide surface maintains near-stoichiometric gallium-to-oxygen composition.

The method may further comprise embodiments wherein the etched gallium oxide surface maintains gallium-oxygen bonding after etching.

The method may further comprise embodiments wherein Raman-active phonon modes of gallium oxide are preserved after etching.

The method may further comprise embodiments wherein the etched surface exhibits no measurable phase transformation after etching.

The method may further comprise embodiments wherein the etched surface exhibits no measurable rotational domain formation after etching.

The method may further comprise embodiments wherein the etching preserves structural integrity, chemical integrity, or both, of the gallium oxide surface.

The method may further comprise embodiments wherein the etching preserves Schottky interface quality in a subsequently fabricated semiconductor device.

The method may further comprise embodiments wherein the etching does not substantially alter a donor concentration profile in a gallium oxide drift layer.

The method may further comprise embodiments wherein the etching does not produce measurable dopant diffusion from a dielectric mask into the gallium oxide.

The method may further comprise embodiments further comprising growing a gallium oxide epitaxial layer in the LPCVD chamber before the etching step.

The method may further comprise embodiments wherein the growing and etching are performed in the same LPCVD reactor.

The method may further comprise embodiments wherein the growing comprises supplying oxygen and gallium to form a gallium oxide epitaxial layer.

The method may further comprise embodiments wherein the growing comprises forming a multilayer gallium oxide structure comprising a buffer layer, a contact layer, and a drift layer.

The method may further comprise embodiments wherein the growing comprises forming doped gallium oxide using one or more dopants selected from silicon (Si), tin (Sn), germanium (Ge), magnesium (Mg), iron (Fe), nitrogen (N), other group-IV dopants, or combinations thereof.

The method may further comprise embodiments wherein the growing comprises introducing an n-type dopant using one or more dopant precursors selected from silicon-containing precursors, tin-containing precursors, germanium-containing precursors, or combinations thereof.

The method may further comprise embodiments wherein the silicon-containing precursor comprises silicon tetrachloride (SiCl₄).

The method may further comprise embodiments wherein the tin-containing precursor comprises a metallic tin source, a tin halide precursor, or both.

The method may further comprise embodiments wherein the germanium-containing precursor comprises a metallic germanium source, a germanium halide precursor, or both.

The method may further comprise embodiments wherein the integrated LPCVD growth and etching process forms a gallium oxide device structure without plasma etching of the gallium oxide.

The method may further comprise embodiments wherein the integrated LPCVD growth and etching process forms a quasi-vertical Schottky barrier diode on an insulating foreign substrate.

The method may further comprise embodiments wherein the integrated LPCVD growth and etching process forms a device comprising a mesa-isolated beta-phase gallium oxide (β-Ga₂O₃) drift region.

Also disclosed, is a semiconductor device fabricated by these methods wherein the device comprises a diode, Schottky barrier diode, trench Schottky barrier diode, transistor, metal-oxide-semiconductor field-effect transistor (MOSFET), fin field-effect transistor (FinFET), vertical transistor, lateral transistor, photodetector, radiation detector, field emitter, sensor, or combinations thereof.

The semiconductor device may further comprise embodiments wherein the device comprises a beta-phase gallium oxide (β-Ga₂O₃) Schottky barrier diode.

The semiconductor device may further comprise embodiments wherein the device comprises a quasi-vertical beta-phase gallium oxide (β-Ga₂O₃) Schottky barrier diode formed on sapphire.

The semiconductor device may further comprise embodiments wherein the device comprises a vertical beta-phase gallium oxide (β-Ga₂O₃) Schottky barrier diode formed on a native beta-phase gallium oxide (β-Ga₂O₃) substrate.

The semiconductor device may further comprise embodiments wherein the etched gallium oxide region defines a mesa isolation region.

The semiconductor device may further comprise embodiments wherein the etched gallium oxide region defines a deep-mesa field-termination structure.

The semiconductor device may further comprise embodiments wherein the etched gallium oxide region defines a trench, fin, channel, recess, field plate recess, cathode access region, anode perimeter structure, edge termination structure, or combinations thereof.

The semiconductor device may further comprise embodiments wherein the etched gallium oxide region redistributes electric field near an anode perimeter.

The semiconductor device may further comprise embodiments wherein the etched gallium oxide region reduces electric-field crowding.

The semiconductor device may further comprise embodiments wherein the etched gallium oxide region increases reverse breakdown voltage relative to an otherwise similar device lacking the etched field-termination structure.

The semiconductor device may further comprise embodiments wherein the etched gallium oxide region maintains forward conduction characteristics relative to an otherwise similar unetched planar device.

The semiconductor device may further comprise embodiments wherein the device exhibits thermionic-emission-dominated current transport.

The semiconductor device may further comprise embodiments wherein the device retains rectifying behavior at temperatures up to about 250 °C.

The semiconductor device may further comprise embodiments wherein the device retains functional electrical behavior after neutron irradiation.

The semiconductor device may further comprise embodiments wherein the device is configured for power electronics, radio-frequency electronics, optoelectronics, space electronics, nuclear electronics, high-temperature electronics, radiation-relevant electronics, or combinations thereof.

Also disclosed is a method of fabricating a quasi-vertical gallium oxide Schottky barrier diode, comprising: (a) growing a multilayer beta-phase gallium oxide (β-Ga₂O₃) epitaxial structure on an insulating sapphire substrate using low-pressure chemical vapor deposition (LPCVD); (b) forming a patterned mask over the multilayer beta-phase gallium oxide (Bβ-Ga₂O₃) epitaxial structure; (c) selectively etching exposed beta-phase gallium oxide (β-Ga₂O₃) regions in an LPCVD chamber using solid-source metallic gallium under oxygen-deficient carrier-gas-mediated conditions; (d) forming a mesa-isolated beta-phase gallium oxide (β-Ga₂O₃) region; (e) forming an ohmic contact to a highly doped beta-phase gallium oxide (β-Ga₂O₃) contact layer; and (f) forming a Schottky contact to a beta-phase gallium oxide (β-Ga₂O₃) drift layer.

The method may further comprise embodiments wherein the multilayer beta-phase gallium oxide (β-Ga₂O₃) epitaxial structure comprises an unintentionally doped buffer layer, an n-type heavily doped contact layer, and an n-type drift layer.

The method may further comprise embodiments wherein the beta-phase gallium oxide (β-Ga₂O₃) drift layer has a thickness in a range of about 0.5 μm to about 20 μm.

The method may further comprise embodiments wherein the mesa isolation etch depth is sufficient to expose at least a portion of an underlying highly doped contact layer.

The method may further comprise embodiments wherein the mesa sidewall comprises an inclined or vertical profile determined by crystallographic anisotropy of beta-phase gallium oxide (β-Ga₂O₃).

The method may further comprise embodiments wherein the insulating sapphire substrate comprises sapphire.

The method may further comprise embodiments wherein the sapphire comprises c-plane sapphire.

The method may further comprise embodiments wherein the c-plane sapphire is on-axis or off-axis.

The method may further comprise embodiments wherein the device exhibits rectifying current-voltage characteristics.

The method may further comprise embodiments wherein the device exhibits low specific on-resistance relative to comparable plasma-etched structures.

The method may further comprise embodiments wherein the resulting device exhibits stable current-voltage behavior from about 25 °C to about 500 °C.

Also disclosed is a method of forming a field-terminated gallium oxide semiconductor device, comprising: (a) providing a gallium oxide layer on a substrate; (b) forming a patterned mask defining a peripheral region adjacent to an active device region; (c) selectively etching the peripheral region within a low-pressure chemical vapor deposition (LPCVD) chamber using gallium vapor generated from solid-source gallium under an inert carrier gas environment to form a recessed mesa structure; and (d) forming an electrical contact structure adjacent to the recessed mesa structure, wherein the recessed mesa structure provides electric-field redistribution at a device periphery.

The method may further comprise embodiments wherein the gallium oxide layer comprises beta-phase gallium oxide (β-Ga₂O₃).

The method may further comprise embodiments wherein the substrate comprises a native gallium oxide substrate.

The method may further comprise embodiments wherein the substrate comprises a heteroepitaxial substrate.

The method may further comprise embodiments wherein the etching is performed under oxygen-deficient conditions.

The method may further comprise embodiments wherein the recessed mesa structure is formed using a thermally driven suboxide reaction.

The method may further comprise embodiments wherein the etching is plasma-free.

The method may further comprise embodiments wherein the recessed mesa structure has a depth greater than about 0.5 μm.

The method may further comprise embodiments wherein the recessed mesa structure has a depth in a range of about 1 μm to about 20 μm.

The method may further comprise embodiments wherein the recessed mesa structure has a depth in a range of about 3 μm to about 15 μm.

The method may further comprise embodiments wherein the recessed mesa structure has a depth in a range of about 4 μm to about 12 μm.

The method may further comprise embodiments wherein the recessed mesa structure has a sidewall angle between about 45 degrees and about 90 degrees.

The method may further comprise embodiments wherein the recessed mesa structure has an inclined sidewall geometry resulting from crystallographic anisotropy.

A method of fabricating and evaluating a radiation-tolerant gallium oxide semiconductor device is also disclosed, comprising: (a) forming a gallium oxide semiconductor structure; (b) defining a device geometry using a plasma-free etching process performed in a low-pressure chemical vapor deposition (LPCVD) environment utilizing solid-source gallium under an inert carrier gas; (c) forming electrical contacts to produce a gallium oxide device; and (d) exposing the gallium oxide device to radiation, wherein the gallium oxide device retains rectifying electrical behavior after radiation exposure.

The method may further comprise embodiments wherein the gallium oxide comprises beta-phase gallium oxide (β-Ga₂O₃).

The method may further comprise embodiments wherein the gallium oxide semiconductor structure comprises a heteroepitaxial layer on a non-native substrate.

The method may further comprise embodiments wherein the non-native substrate comprises sapphire, silicon, silicon carbide, gallium nitride, diamond, or combinations thereof.

The method may further comprise embodiments wherein the gallium oxide device comprises a Schottky barrier diode.

The method may further comprise embodiments wherein the plasma-free etching defines a mesa or quasi-vertical device structure.

The method may further comprise embodiments wherein the radiation comprises neutron radiation.

The method may further comprise embodiments wherein the neutron radiation comprises fast neutrons.

The method may further comprise embodiments wherein the neutron radiation comprises a fluence in a range from about 1×10¹² to about 1×10¹⁷ n/cm².

The method may further comprise embodiments wherein the neutron radiation comprises a 1 MeV equivalent neutron fluence.

The method may further comprise embodiments wherein the neutron radiation comprises a fluence of about 1×10¹⁵ n/cm².

The method may further comprise embodiments wherein the radiation comprises gamma radiation.

The method may further comprise embodiments wherein the gamma radiation comprises a total ionizing dose in a range from about 1 mrad(Si) to about 20 Mrad(Si).

The method may further comprise embodiments wherein the gamma radiation induces defect states associated with charge trapping or interface modification in the gallium oxide.

The method may further comprise embodiments wherein the radiation comprises proton radiation.

The method may further comprise embodiments wherein the proton radiation comprises a fluence in a range from about 1×10¹⁰ to about 1×10¹⁸ p/cm².

The method may further comprise embodiments wherein the proton radiation induces displacement damage and defect generation within the gallium oxide.

The method may further comprise embodiments wherein the radiation comprises one or more of neutron radiation, gamma radiation, or proton radiation.

The method may further comprise embodiments wherein the radiation comprises mixed-field radiation exposure.

The method may further comprise embodiments wherein the radiation is representative of a space, nuclear, or high-energy radiation environment.

Also disclosed is a system for etching gallium oxide, comprising: (a) a low-pressure chemical vapor deposition (LPCVD) chamber configured to operate under low-pressure conditions; (b) a gallium source configured to generate gallium vapor; (c) a substrate holder configured to hold a gallium oxide substrate or epitaxial wafer downstream from the gallium source; (d) a carrier gas inlet configured to introduce an inert carrier gas into the LPCVD chamber; (e) a temperature control system configured to heat the gallium source and the gallium oxide substrate or epitaxial wafer; and (f) a pumping system configured to remove volatile gallium suboxide species from the LPCVD chamber.

The system may further comprise embodiments wherein the LPCVD chamber comprises a horizontal tube reactor.

The system may further comprise embodiments wherein the gallium source comprises solid-source metallic gallium.

The system may further comprise embodiments wherein the gallium source is positioned upstream from the substrate holder.

The system may further comprise embodiments wherein the gallium source and the substrate holder are positioned such that a source-to-substrate spacing is adjustable.

The system may further comprise embodiments wherein the source-to-substrate spacing is adjustable from about 0.5 cm to about 20 cm.

The system may further comprise embodiments wherein the carrier gas inlet is configured to introduce argon, nitrogen, helium, neon, or combinations thereof.

The system may further comprise embodiments wherein the pumping system is configured to maintain a pressure from about 0.1 Torr to about 10 Torr.

The system may further comprise embodiments wherein the temperature control system is configured to heat the gallium oxide substrate or epitaxial wafer to about 400 °C to about 1500 °C.

The system may further comprise embodiments wherein the LPCVD chamber is configured for both gallium oxide epitaxial growth and gallium oxide etching.

The system may further comprise embodiments wherein the LPCVD chamber is configured to perform plasma-free gallium oxide etching by carrier-gas-mediated transport of gallium vapor.

The system may further comprise embodiments wherein the LPCVD chamber is configured to operate under oxygen-deficient conditions.

The system may further comprise embodiments wherein the LPCVD chamber is configured to transport gallium vapor to the gallium oxide substrate or epitaxial wafer by diffusion, convection, carrier gas flow, or combinations thereof.

The system may further comprise embodiments wherein the LPCVD chamber comprises a multi-zone furnace.

The system may further comprise embodiments wherein the multi-zone furnace is configured to independently control a gallium source temperature and a substrate temperature.

The system may further comprise embodiments wherein the LPCVD chamber is configured to tune an etch rate by controlling temperature, pressure, carrier gas flow rate, source-to-substrate spacing, or combinations thereof.

The system may further comprise embodiments wherein the LPCVD chamber is configured to produce crystallographically anisotropic etching of gallium oxide.

The system may further comprise embodiments wherein the system is configured to form fins, trenches, mesas, recesses, sidewalls, field-termination structures, or combinations thereof.

The system may further comprise embodiments wherein the LPCVD chamber is configured for wafer-scale processing.

The system may further comprise embodiments wherein the LPCVD chamber is configured to process 2-inch, 4-inch, 6-inch, or larger gallium oxide wafers.

The method may further comprise embodiments wherein the gallium oxide is doped with silicon, tin, germanium, magnesium, iron, nitrogen, or combinations thereof.

The method may further comprise embodiments wherein the gallium oxide comprises an unintentionally doped layer, a lightly doped layer, a moderately doped layer, a heavily doped layer, or combinations thereof.

The method may further comprise embodiments wherein the etching exposes an underlying highly doped contact layer.

The method may further comprise embodiments wherein the etching electrically isolates adjacent device regions.

The method may further comprise embodiments wherein the etching forms an access region for ohmic contact formation.

The method may further comprise embodiments wherein the etching forms a device geometry that controls current flow.

The method may further comprise embodiments wherein the etching forms a device geometry that controls electric-field distribution.

The method may further comprise embodiments wherein the etching forms a beta-phase gallium oxide (β-Ga₂O₃) fin for a vertical transistor or fin field-effect transistor (FinFET).

The method may further comprise embodiments wherein the etching forms a beta-phase gallium oxide (β-Ga₂O₃) trench for a trench diode or trench transistor.

The method may further comprise embodiments wherein the etching forms a mesa for a Schottky barrier diode.

The method may further comprise embodiments wherein the etching forms a deep mesa for edge termination.

The method may further comprise embodiments wherein the etching forms a beveled or inclined sidewall.

The method may further comprise embodiments wherein the etching forms a substantially vertical sidewall.

The method may further comprise embodiments wherein the etching forms an inclined sidewall having a sidewall angle from about 15 degrees to about 90 degrees.

The method may further comprise embodiments wherein the process is compatible with wafer-scale processing.

The method may further comprise embodiments wherein the process is compatible with 2-inch, 4-inch, 6-inch, or larger wafers.

The method may further comprise embodiments wherein the process enables fabrication of gallium oxide devices without chlorine-based plasma etching.

The method may further comprise embodiments wherein the process enables fabrication of gallium oxide devices without wet chemical etching of the gallium oxide.

The method may further comprise embodiments wherein the process enables fabrication of gallium oxide devices without metal-assisted chemical etching of the gallium oxide.

The method may further comprise embodiments wherein the process uses metallic gallium as a chemical etchant in a carrier-gas-mediated LPCVD environment.

The method may further comprise embodiments wherein the process uses an inert gas flow to regulate gallium delivery, volatile suboxide removal, etch rate, anisotropy, or combinations thereof.

The method may further comprise embodiments wherein the etching is performed after LPCVD growth without removing the gallium oxide wafer from a processing platform.

The method may further comprise embodiments wherein the etching is performed after transferring the gallium oxide wafer from an LPCVD growth condition to an LPCVD etching condition.

The method may further comprise embodiments wherein the gallium source and the gallium oxide substrate or epitaxial wafer are maintained at substantially the same temperature during etching.

The method may further comprise embodiments wherein the gallium source and the gallium oxide substrate or epitaxial wafer are maintained at different temperatures during etching.

The method may further comprise embodiments wherein gallium vapor availability at the substrate surface is controlled by source-to-substrate distance.

The method may further comprise embodiments wherein increasing source-to-substrate distance reduces the etch rate.

The method may further comprise embodiments wherein increasing temperature increases surface reaction kinetics.

The method may further comprise embodiments wherein increasing carrier gas flow increases gallium transport up to an optimum flow rate.

The method may further comprise embodiments wherein excessive carrier gas flow decreases etch rate by reducing residence time or diluting gallium vapor near the surface.

The method may further comprise embodiments wherein the etching proceeds through a vapor-transport-limited regime, a surface-reaction-limited regime, or both.

The method may further comprise embodiments wherein the etching is tunable between transport-limited and reaction-limited regimes.

The method may further comprise embodiments wherein the etching produces reduced sidewall roughness compared with plasma-etched gallium oxide.

The method may further comprise embodiments wherein the etching enables a gallium oxide device for space, defense, nuclear, high-temperature, high-voltage, high-power, or radiation-relevant applications.

Also disclosed is a gallium oxide structure formed by the described methods herein wherein the structure comprises an etched beta-phase gallium oxide (β-Ga₂O₃) fin, trench, mesa, recess, sidewall, field-termination region, or combinations thereof.

The gallium oxide structure may further comprise embodiments wherein the structure comprises an etched surface formed by thermally activated gallium suboxide generation in an LPCVD chamber.

The gallium oxide structure may further comprise embodiments wherein the structure comprises a plasma-damage-free etched gallium oxide surface.

The gallium oxide structure may further comprise embodiments wherein the structure comprises an orientation-selective etched profile.

The gallium oxide structure may further comprise embodiments wherein the structure comprises a mesa-terminated beta-phase gallium oxide (β-Ga₂O₃) Schottky barrier diode.

The gallium oxide structure may further comprise embodiments wherein the structure comprises a quasi-vertical beta-phase gallium oxide (β-Ga₂O₃) Schottky barrier diode on sapphire.

The gallium oxide structure may further comprise embodiments wherein the structure comprises a vertical beta-phase gallium oxide (β-Ga₂O₃) Schottky barrier diode on a native beta-phase gallium oxide (β-Ga₂O₃) substrate.

The gallium oxide structure may further comprise embodiments wherein the structure comprises a beta-phase gallium oxide (ββ-Ga₂O₃) device retaining functional rectifying behavior after radiation exposure.

It would be appreciated by those skilled in the art that various changes and modifications can be made to the illustrated embodiments without departing from the spirit of the present invention. All such modifications and changes are intended to be within the scope of the present invention except as limited by the scope of the appended claims.

### REFERENCES

These references are incorporated herein by reference in their entirety.
1. A. J. Green, J. Speck, G. Xing, P. Moens, F. Allerstam, K. Gumaelius, T. Neyer, A. Arias-Purdue, V. Mehrotra, A. Kuramata, K. Sasaki, S. Watanabe, K. Koshi, J. Blevins, O. Bierwagen, S. Krishnamoorthy, K. Leedy, A. R. Arehart, A. T. Neal, S. Mou, S. A. Ringel, A. Kumar, A. Sharma, K. Ghosh, U. Singisetti, W. Li, K. Chabak, K. Liddy, A. Islam, S. Rajan, S. Graham, S. Choi, Z. Cheng and M. Higashiwaki, APL Materials 10(2), 029201 (2022).
2. M. Higashiwaki, K. Sasaki, A. Kuramata, T. Masui and S. Yamakoshi, Applied Physics Letters 100(1), 013504 (2012).
3. M. Higashiwaki and G. H. Jessen, Appl. Phys. Lett. 112, 060401(2018 ).
4. A. Kuramata, K. Koshi, S. Watanabe, Y. Yamaoka, T. Masui and S. Yamakoshi, Japanese Journal of Applied Physics 55(12), 1202 A1202 (2016).
5. S. J. Pearton, F. Ren, M. Tadjer and J. Kim, Journal of Applied Physics 124(22), 220901 (2018).
6. J. Zhang, P. Dong, K. Dang, Y. Zhang, Q. Yan, H. Xiang, J. Su, Z. Liu, M. Si and J. Gao, Nature communications 13(1), 3900 (2022).
7. P. Dong, J. Zhang, Q. Yan, Z. Liu, P. Ma, H. Zhou and Y. Hao, IEEE Electron Device Letters 43(5), 765-768 (2022).
8. S. J. Pearton, J. Yang, P. H. CaryIV, F. Ren, J. Kim, M. J. Tadjer and M. A. Mastro, Applied Physics Reviews 5(1), 011301 (2018).
9. J. Kim, S. J. Pearton, C. Fares, J. Yang, F. Ren, S. Kim and A. Y. Polyakov, Journal of Materials Chemistry C 7(1), 10-24 (2019).
10. L. Zhou, H. Chen, T. Xu, J. Ruan, Y. Lai, Y. Deng, J. Chen, X. Zou, X. Lu and L. Chen, Applied Physics Letters 124(1), 013506 (2024).
11. M. H. Wong, A. Takeyama, T. Makino, T. Ohshima, K. Sasaki, A. Kuramata, S. Yamakoshi and M. Higashiwaki, Applied Physics Letters 112(2), 023503 (2018).
12. S. A. Khan, S. Saha, U. Singisetti and A. Bhuiyan, Journal of Applied Physics 136(22), 225701 (2024).
13. A. Bhuiyan, Z. Feng, L. Meng and H. Zhao, Journal of Applied Physics, 133, 211103 (2023).
14. M. Lingyu, Z. Feng, A. Bhuiyan, H. L. Huang, J. Hwang and H. Zhao, Journal of Vacuum Science & Technology A 40, 062706 (2022).
15. A. Bhuiyan, Z. Feng, L. Meng, A. Fiedler, H.-L. Huang, A. T. Neal, E. Steinbrunner, S. Mou, J. Hwang, S. Rajan and H. Zhao, Journal of Applied Physics 131(14), 145301 (2022).
16. C. Peterson, A. Bhattacharyya, K. Chanchaiworawit, R. Kahler, S. Roy, Y. Liu, S. Rebollo, A. Kallistova, T. E. Mates and S. Krishnamoorthy, Applied Physics Letters 125(18), 182103 (2024).
17. Z. Feng, A. Bhuiyan, M. R. Karim and H. Zhao, Applied Physics Letters 114(25), 250601 (2019).
18. Z. Feng, A. Bhuiyan, N. K. Kalarickal, S. Rajan and H. Zhao, Applied Physics Letters 117(22), 222106 (2020).
19. A. Mauze, Y. Zhang, T. Itoh, E. Ahmadi and J. S. Speck, Applied Physics Letters 117(22), 222102 (2020).
20. E. Ahmadi, O. S. Koksaldi, S. W. Kaun, Y. Oshima, D. B. Short, U. K. Mishra and J. S. Speck, Applied Physics Express 10(4), 041102 (2017).
21. Z. Wen, X. Zhai, C. Lee, S. Kosanovic, Y. Kim, A. T. Neal, T. Asel, S. Mou and E. Ahmadi, Applied Physics Letters 124(12), 122101 (2024).
22. J. H. Leach, K. Udwary, J. Rumsey, G. Dodson, H. Splawn and K. R. Evans, APL Materials 7(2), 022504 (2018).
23. Q. T. Thieu, D. Wakimoto, Y. Koishikawa, K. Sasaki, K. Goto, K. Konishi, H. Murakami, A. Kuramata, Y. Kumagai and S. Yamakoshi, Japanese Journal of Applied Physics 56(11), 110310 (2017).
24. S. A. Khan, A. Ibreljic, S. Margiotta and A. Bhuiyan, Applied Physics Letters 126(1), 012103 (2025).
25. Y. Zhang, Z. Feng, M. R. Karim and H. Zhao, Journal of Vacuum Science & Technology A 38(5), 050806 (2020).
26. S. Rafique, L. Han, M. J. Tadjer, J. A. Freitas, N. A. Mahadik and H. Zhao, Applied Physics Letters 108(18), 182105 (2016).
27. W. Li, K. Nomoto, Z. Hu, D. Jena and H. G. Xing, IEEE Electron Device Letters 41(1), 107-110(2020).
28. W. Li, Z. Hu, K. Nomoto, Z. Zhang, J.-Y. Hsu, Q. T. Thieu, K. Sasaki, A. Kuramata, D. Jena and H. G. Xing, Applied Physics Letters 113(20), 202101 (2018).
29. W. Li, K. Nomoto, Z. Hu, N. Tanen, K. Sasaki, A. Kuramata, D. Jena and H. G. Xing, presented at the 2018 76th Device Research Conference (DRC), 2018 (unpublished).
30. S. Dhara, N. K. Kalarickal, A. Dheenan, S. I. Rahman, C. Joishi and S. Rajan, Applied Physics Letters 123(2), 023503 (2023).
31. S. Saha, W. Amir, J. Liu, L. Meng, D. Yu, H. Zhao and U. Singisetti, IEEE Electron Device Letters, 1-1 (2025).
32. Y. Ma, X. Zhou, W. Tang, X. Zhang, G. Xu, L. Zhang, T. Chen, S. Dai, C. Bian, B. Li, Z. Zeng and S. Long, IEEE Electron Device Letters 44(3), 384-387 (2023).
33. H.-C. Huang, Z. Ren, A. Bhuiyan, Z. Feng, Z. Yang, X. Luo, A. Q. Huang, A. Green, K. Chabak and H. Zhao, Applied Physics Letters 121(5), 052102 (2022).
34. Z. Ren, H.-C. Huang, H. Lee, C. Chan, H. C. Roberts, X. Wu, A. Waseem, A. Bhuiyan, H. Zhao, W. Zhu and X. Li, Applied Physics Letters 123(4), 043505 (2023).
35. G. Alfieri, A. Mihaila, P. Godignon, J. B. Varley and L. Vines, Journal of Applied Physics 130(2), 025701 (2021).
36. J. Yang, Z. Sparks, F. Ren, S. J. Pearton and M. Tadjer, Journal of Vacuum Science & Technology B 36(6), 061201 (2018).
37. J. Yang, S. Ahn, F. Ren, R. Khanna, K. Bevlin, D. Geerpuram, S. J. Pearton and A. Kuramata, Applied Physics Letters 110(14), 142101 (2017).
38. J. Yang, F. Ren, R. Khanna, K. Bevlin, D. Geerpuram, L.-C. Tung, J. Lin, H. Jiang, J. Lee, E. Flitsiyan, L. Chernyak, S. J. Pearton and A. Kuramata, Journal of Vacuum Science & Technology B 35(5), 051201 (2017).
39. A. Y. Polyakov, I.-H. Lee, N. B. Smirnov, E. B. Yakimov, I. V. Shchemerov, A. V. Chernykh, A. I. Kochkova, A. A. Vasilev, P. H. Carey, F. Ren, D. J. Smith and S. J. Pearton, APL Materials 7(6), 061102 (2019).
40. Z. Hu, K. Nomoto, W. Li, Z. Zhang, N. Tanen, Q. T. Thieu, K. Sasaki, A. Kuramata, T. Nakamura, D. Jena and H. G. Xing, Applied Physics Letters 113(12), 122103 (2018).
41. Y. Zhang, A. Mauze and J. S. Speck, Applied Physics Letters 115(1), 013501 (2019).
42. S. Rebollo, T. Itoh, S. Krishnamoorthy and J. S. Speck, Applied Physics Letters 125(1), 012102 (2024).
43. H. Okumura and T. Tanaka, Japanese Journal of Applied Physics 58(12), 120902 (2019).
44. A. R. Gutierrez, J. A. Spencer, A. G. Jacobs, Y. Qin, J. R. Hajzus, H. N. Masten, E. Rocco, K. D. Hobart, T. J. Anderson, Y. Zhang, A. Kuramata and M. J. Tadjer, Journal of Vacuum Science & Technology A 43(3), 033210 (2025).
45. M. Kim, H.-C. Huang, J. D. Kim, K. D. Chabak, A. R. K. Kalapala, W. Zhou and X. Li, Applied Physics Letters 113(22), 222104 (2018).
46. H.-C. Huang, M. Kim, X. Zhan, K. Chabak, J. D. Kim, A. Kvit, D. Liu, Z. Ma, J.-M. Zuo and X. Li, ACS nano 13(8), 8784-8792 (2019).
47. H.-C. Huang, Z. Ren, C. Chan and X. Li, Journal of Materials Research 36(23), 4756-4770 (2021).
48. T. Oshima and Y. Oshima, Applied Physics Letters 122(16), 162102 (2023).
49. T. Oshima and Y. Oshima, Applied Physics Express 16(6), 066501 (2023).
50. T. Oshima and Y. Oshima, Applied Physics Letters 124(4), 042110 (2024).
51. Y. Oshima and T. Oshima, Japanese Journal of Applied Physics 62(8), 080901 (2023).
52. T. Oshima and Y. Oshima, Japanese Journal of Applied Physics 64(1), 018003 (2025).
53. T. Oshima and Y. Oshima, AIP Advances 15(5), 055207 (2025).
54. T. Oshima, R. Togashi and Y. Oshima, Science and Technology of Advanced Materials 25(1), 2378683 (2024).
55. N. K. Kalarickal, A. Fiedler, S. Dhara, H.-L. Huang, A. A. U. Bhuiyan, M. W. Rahman, T. Kim, Z. Xia, Z. J. Eddine and A. Dheenan, Applied Physics Letters 119(12), 123503 (2021).
56. Y. Oshima, E. Ahmadi, S. Kaun, F. Wu and J. S. Speck, Semiconductor Science and Technology 33(1), 015013 (2017).
57. A. Katta, F. Alema, W. Brand, A. Gilankar, A. Osinsky and N. K. Kalarickal, Journal of Applied Physics 135(7), 075705 (2024).
58. C. A. Gorsak, H. J. Bowman, K. R. Gann, J. T. Buontempo, K. T. Smith, P. Tripathi, J. Steele, D. Jena, D. G. Schlom, H. G. Xing, M. O. Thompson and H. P. Nair, Applied Physics Letters 125(24), 242103 (2024).
59. R. Schewski, K. Lion, A. Fiedler, C. Wouters, A. Popp, S. V. Levchenko, T. Schulz, M. Schmidbauer, S. B. Anooz, R. Grüneberg, Z. Galazka, G. Wagner, K. Irmscher, M. Scheffler, C. Draxl and M. Albrecht, APL Materials 7(2), 022515 (2019).
60. C.-H. Lin, K. Ema, S. Masuya, Q. T. Thieu, R. Sakaguchi, K. Sasaki and A. Kuramata, Japanese Journal of Applied Physics 62(SF), SF1005 (2023).
61. S. A. Khan, A. Ibreljic, S. Margiotta and A. F. M. A. U. Bhuiyan, Appl. Phys. Lett. 126 (1) (2025).
62. S. Rafique, L. Han, A. T. Neal, S. Mou, J. Boeckl and H. Zhao, physica status solidi (a) 215 (2), 1700467 (2018).

What is claimed is:

1. A method for etching gallium oxide, comprising:
placing a substrate comprising gallium oxide inside a low-pressure chemical vapor deposition (LPCVD) chamber, wherein the gallium oxide is unintentionally doped or doped with one or more dopants;
providing a gallium source to the LPCVD chamber;
generating gallium vapor from the gallium source under reduced-pressure conditions within the LPCVD chamber;
transporting the gallium vapor to a surface of the substrate within the LPCVD chamber; and
etching the gallium oxide by a thermally activated reaction between gallium and gallium oxide to form and remove volatile gallium suboxide species, wherein the reaction is sustained by carrier-gas-mediated transport of gallium vapor to the surface.

2. The method of claim 1, wherein the dopants are selected from the group consisting of silicon, tin, germanium, magnesium, nitrogen, iron, and combinations thereof.

3. The method of claim 1, wherein the substrate comprises one of a homoepitaxial layer on a native gallium oxide substrate or a heteroepitaxial layer on a foreign substrate.

4. The method of claim 1, wherein the gallium vapor is transported by diffusion, convection, carrier gas flow, or combinations thereof, and the etching is governed by vapor-transport-limited kinetics, surface-reaction-limited kinetics, or coupled vapor-transport and surface-reaction kinetics.

5. The method of claim 1, wherein the gallium oxide comprises one or more polymorphs selected from alpha-phase, beta-phase, kappa-phase, epsilon-phase, gamma-phase, or delta-phase gallium oxide, and combinations thereof.

6. The method of claim 3, wherein the foreign substrate comprises sapphire, silicon, silicon carbide, gallium nitride, aluminum nitride, diamond, and combinations thereof.

7. The method of claim 1, wherein the gallium source comprises solid metallic gallium positioned inside the LPCVD chamber.

8. The method of claim 1, wherein the etching is performed in the absence of plasma generation and ion bombardment, under oxygen-deficient or oxygen-free conditions.

9. The method of claim 1, wherein the etching is performed as selective-area etching, blanket etching, and combinations thereof.

10. The method of claim 9, wherein the selective-area etching comprises forming a mask defining exposed regions, the mask comprising silicon dioxide, silicon nitride, aluminum oxide, hafnium oxide, titanium oxide, or combinations thereof, and wherein the etching forms one or more structures selected from the group consisting of trenches, mesas, fins, recesses, sidewalls, and field-termination structures.

11. The method of claim 1, wherein an etch rate is controlled by adjusting a Ga-source-to-substrate spacing to regulate gallium vapor availability at the surface.

12. The method of claim 1, wherein an etch rate is controlled by adjusting a gallium source temperature, a substrate temperature, carrier gas flow, and combinations thereof.

13. The method of claim 1, wherein the etching is performed at a temperature from about 300 °C to about 1500 °C and a pressure from about 0.1 Torr to about 500 Torr.

14. The method of claim 1, wherein the etching operates in a vapor-transport-limited regime, a surface-reaction-limited regime, or a transition between the two.

15. The method of claim 1, wherein the etching is controlled by regulating gallium vapor concentration at the surface through carrier-gas-mediated transport under low-pressure conditions.

16. The method of claim 1, wherein the etching produces orientation-dependent geometry enabling control of sidewall angle, fin width, mesa geometry, trench shape, or electric-field distribution.

17. The method of claim 1, wherein the etched gallium oxide surface is substantially free of plasma-induced damage and preserves structural integrity and chemical stoichiometry.

18. The method of claim 1, further comprising, growing a gallium oxide epitaxial layer in the low-pressure chemical vapor deposition chamber prior to etching, wherein the growth and etching are performed in the same reactor, wherein the growth comprises blanket growth, selective-area growth, and combinations thereof, and wherein the etching comprises selective-area etching, blanket etching, and combinations thereof.

19. The method of claim 18, wherein the etching is performed in-situ within the LPCVD chamber using carrier-gas-mediated transport of gallium vapor without removing the gallium oxide substrate or epitaxial wafer after growth.

20. A system for etching gallium oxide, comprising:
a low-pressure chemical vapor deposition (LPCVD) chamber configured and arranged to operate under reduced-pressure conditions;
a gallium source disposed within the LPCVD chamber, the gallium source generating a gallium vapor;
a substrate holder supporting a gallium oxide substrate within the LPCVD chamber at a spacing from the gallium source;
a carrier gas delivery mechanism configured and arranged to transport the gallium vapor to a surface of the substrate;
a temperature control mechanism configured and arranged to control temperatures of the gallium source and the gallium oxide substrate; and
a pumping system configured and arranged to remove volatile gallium suboxide species generated by a reaction between gallium vapor and gallium oxide of the gallium oxide substrate;
whereby the gallium oxide is etched via a thermally activated reaction forming volatile gallium suboxide under plasma-free conditions.

21. The system of claim 20, wherein an adjustable source-to-substrate spacing, temperatures of the gallium source and the substrate, and a carrier gas flow rate are configured and arranged to control etch rate and etch profile by regulating gallium vapor transport and surface-reaction kinetics.
